(19) United States
(12) Patent Application Publication
(10) Pub. No.: US 2023/0307541 A1
(43) Pub. Date: Sep. 28, 2023

(54) TRANSISTOR GATE STACKS WITH THICK HYSTERETIC ELEMENTS

(71) Applicant: Intel Corporation, Santa Clara, CA (US)

(72) Inventors: Abhishek A. Sharma, Hillsboro, OR (US); Wilfred Gomes, Portland, OR (US); Tahir Ghani, Portland, OR (US); Anand S. Murthy, Portland, OR (US); Pushkar Sharad Ranade, San Jose, CA (US); Sagar Suthram, Portland, OR (US)

(73) Assignee: Intel Corporation, Santa Clara, CA (US)

(21) Appl. No.: 17/702,593

(22) Filed: Mar. 23, 2022

(51) Int. Cl. H01L 29/78; H01L 29/423; H01L 29/51; H01L 29/66

(52) U.S. Cl. CPC H01L 29/78391; H01L 29/42364; H01L 29/516; H01L 29/6684

(57) ABSTRACT

Disclosed herein are transistor gate-channel arrangements with transistor gate stacks that include thick hysteretic elements (i.e., hysteretic elements having a thickness of at least 10-15 nanometers, e.g., between 55 and 100 nanometers), and related methods and devices. Transistor gate stacks disclosed herein include a multilayer gate insulator having a thick hysteretic element and an interface layer, where the thick hysteretic element is between the interface layer and a gate electrode material, and the interface layer is between the thick hysteretic element and a channel material of a transistor. The interface layer may be a dielectric material with an effective dielectric constant of at least 20 and/or be a dielectric material that is thinner than about 3 nanometers. Such an interface layer may help improve gate control and allow use of thick hysteretic elements while maintaining transistor performance in terms of, e.g., gate leakage, carrier mobility, and subthreshold swing.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each contact becomes increasingly significant. Careful design of transistors may help with such an optimization.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1H are cross-sectional side views of a transistor gate-channel arrangement including a transistor gate stack with a thick hysteretic element, in accordance with various embodiments.

FIGS. 2-6 are cross-sectional side views of example single-gate transistors including a transistor gate stack with a thick hysteretic element, in accordance with various embodiments.

FIGS. 7-9 are cross-sectional side views of example double-gate transistors including a transistor gate stack with a thick hysteretic element, in accordance with various embodiments.

FIGS. 10A and 10B are perspective and cross-sectional side views, respectively, of an example fin-based field-effect transistor (FinFET) including a transistor gate stack with a thick hysteretic element, in accordance with various embodiments.

FIGS. 11A and 11B are perspective and cross-sectional side views, respectively, of an example all-around gate transistor including a transistor gate stack with a thick hysteretic element, in accordance with various embodiments.

FIG. 12 is a flow diagram of an example method of manufacturing a transistor gate stack with a thick hysteretic element, in accordance with various embodiments.

FIGS. 13A and 13B are top views of a wafer and dies that may include one or more transistor gate stacks with thick hysteretic elements in accordance with any of the embodiments disclosed herein.

FIG. 14 is a cross-sectional side view of an IC device that may include one or more transistor gate stacks with thick hysteretic elements in accordance with any of the embodiments disclosed herein.

FIG. 15 is a cross-sectional side view of an IC device assembly that may include one or more transistor gate stacks with thick hysteretic elements in accordance with any of the embodiments disclosed herein.

FIG. 16 is a block diagram of an example computing device that may include one or more transistor gate stacks with thick hysteretic elements in accordance with any of the embodiments disclosed herein.

FIG. 17 is a block diagram of an example processing device that may include one or more transistor gate stacks with thick hysteretic elements in accordance with any of the embodiments disclosed herein.

### DETAILED DESCRIPTION

Disclosed herein are transistor gate-channel arrangements with transistor gate stacks that include thick hysteretic elements, and related methods and devices. The systems, methods, and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating transistor gate stacks with thick hysteretic elements and associated arrangements (e.g., transistor gate-channel arrangements with thick hysteretic elements) and devices (e.g., IC devices implementing transistor gate stacks with thick hysteretic elements) as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

The performance of a transistor may depend on the number of factors. For example, some transistors include gates that include a gate insulator, e.g., a gate dielectric such as a high-k dielectric, between a gate electrode and a semiconducting channel material. In such transistors, a stack of a gate insulator and a gate electrode material is typically referred to as a “transistor gate stack” and careful selection of the gate insulator is important for optimal performance.

In some implementations, it may be desirable to include a hysteretic material or a hysteretic arrangement (together referred to as a “hysteretic element”) in a gate stack of a transistor, either instead of or in addition to a gate dielectric. Transistors in which a gate insulator includes a hysteretic element may be described as “hysteretic transistors” and may be used to implement hysteretic memory. Hysteretic memory refers to a memory technology employing hysteretic materials or hysteretic arrangements, where a material or an arrangement may be described as “hysteretic” if it exhibits the dependence of its state on the history of the material (e.g., on a previous state of the material). Ferroelectric (FE) and antiferroelectric (AFE) materials are examples of hysteretic materials. A stack of two or more layers of different materials arranged to exhibit charge-trapping phenomena is an example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, even though there is typically no iron (Fe) present in FE or AFE materials.

A stack of alternating layers of materials, configured to exhibit charge-trapping, is an example of a hysteretic arrangement. Such a stack may include as little as two layers of materials, one of which is a charge-trapping layer (i.e., a layer of a material configured to trap charges when a volage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the number of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high-speed writing. In addition, hysteretic memories may be manufactured using processes compatible with the standard complementary metal-oxide-semiconductor (CMOS) technology. Therefore, over the last few years, these types of memories have emerged as promising candidates for many growing applications.

Including hysteretic elements in gate stacks of transistors is far from trivial. On one hand, using thinner gate insulators is desirable because thinner gate insulators help increase the gate field and, therefore, improve the switching ratio of a transistor through better gate control. As is known in the art, the switching ratio is a measure of a ratio of a current (Ion) between source and drain terminals of a transistor when the transistor is supposed to be on and a current (loff) between source and drain terminals of a transistor when the transistor is supposed to be off. However, simply reducing the thickness of a gate insulator leads to increased gate leakage, where gate leakage refers to a current flowing between a source or a drain terminal and a gate terminal of a transistor. This problem is particularly noticeable at room temperatures because the thermal energy is significantly higher compared to lower-temperature operation and, therefore, trap assisted tunnelling, Schottky emission, and other transport modes are active. Operating transistors at lower temperatures may provide some help in that the thermal energy of the carriers may be reduced since the thermal energy is exponentially dependent on the temperature, thus reducing gate leakage, while simultaneously supporting higher mobility due to reduced scattering at lower temperatures and steeper subthreshold swing. Nevertheless, even lower operating temperatures cannot sufficiently suppress certain leakage modes such as direct tunnelling when using very thin gate insulators. Furthermore, achieving hysteretic behavior in thin layers of hysteretic elements, e.g., in hysteretic elements that are thinner than about 3-5 nanometers, can be very challenging. For example, for doped hafnium oxide, a material that is often used as an FE/AFE material, correct crystallographic phase (e.g., a tetragonal and/or an orthorhombic phase) cannot be easily achieved unless a layer of doped hafnium oxide is relatively thick, e.g., at least about 10-15 nanometers, preferably at least 50 nanometers. Still further, for memory applications, a thickness of a hysteretic element in a gate stack should be at least about 5-10 nanometers to provide sufficient storage capacity, which causes the above-described challenges in achieving adequate gate control when using relatively thick gate insulators.

Embodiments of the present disclosure are based on recognition that using an additional interface layer in a transistor gate stack may allow employing a relatively thick hysteretic element while realizing sufficient gate control. In context of the present disclosure, a hysteretic element is described as a “thick hysteretic element” if it has a thickness of at least about 10-15 nanometers, e.g., of at least about 35 nanometers or at least about 50 nanometers, such as between about 50 and 110 nanometers, or between about 55 and 100 nanometers. Transistor gate stacks disclosed herein include a multilayer gate insulator having a thick hysteretic element and an interface layer, where the thick hysteretic element is between the interface layer and a gate electrode material, and the interface layer is between the thick hysteretic element and a channel material of a transistor. An interface layer may be a layer of a material that is electrically thinner than conventional gate dielectrics used in transistor gates. To that end, the interface layer may be a high-k dielectric with an effective dielectric constant (k-value) of at least 20 and/or be a dielectric material that is thinner than about 3 nanometers, e.g., thinner than about 1 nanometer (e.g., be a single atomic monolayer or may include just a few atomic monolayers). In some embodiments, an interface layer may directly border (e.g., be in contact with) a channel material of choice and may be sandwiched between (e.g., be in contact with each of) the channel material and the hysteretic element. In other embodiments, another, relatively thin layer of a hysteretic material (e.g., a layer that has a thickness less than about 3 nanometers) may be provided between the interface layer and the channel material, which may be advantageous in terms of decreasing the number of defects at the interface with the channel material. Interface layers as described herein may help increase the gate field at or near an interface between a channel material and a hysteretic element, which, in turn, may help maintain carrier mobility in short-channel devices and, therefore, ensure adequate transistor performance in terms of, e.g., gate leakage, carrier mobility, and subthreshold swing even when the hysteretic element is thick. In other words, providing such interface layers may help improve gate control and allow use of thick hysteretic elements while maintaining transistor performance in terms of, e.g., gate leakage, carrier mobility, and subthreshold swing. Transistor gate stacks with thick hysteretic elements, disclosed herein, may enable the use of a wider array of hysteretic elements, while achieving desirable gate control, than what can be realized using conventional approaches. Functionality of transistors with thick hysteretic elements may be improved further if such transistors are operated at relatively low temperatures, e.g., below about 200 Kelvin degrees or below about 20 Kelvin degrees, because at lower temperatures Fermi level is relatively flat (e.g., it does not smear), which allows using thicker gate insulators while maintaining adequate gate control.

In the following detailed description, various aspects of the illustrative implementations may be described using terms commonly employed by those skilled in the art to convey the substance of their work to others skilled in the art. For example, in context of source/drain (S/D) regions, the term “region” may be used interchangeably with the terms “contact” and “terminal” of a transistor. In another example, as used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” “sulfide,” etc. refer to compounds containing, respectively, oxygen, carbon, nitrogen, sulfur, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

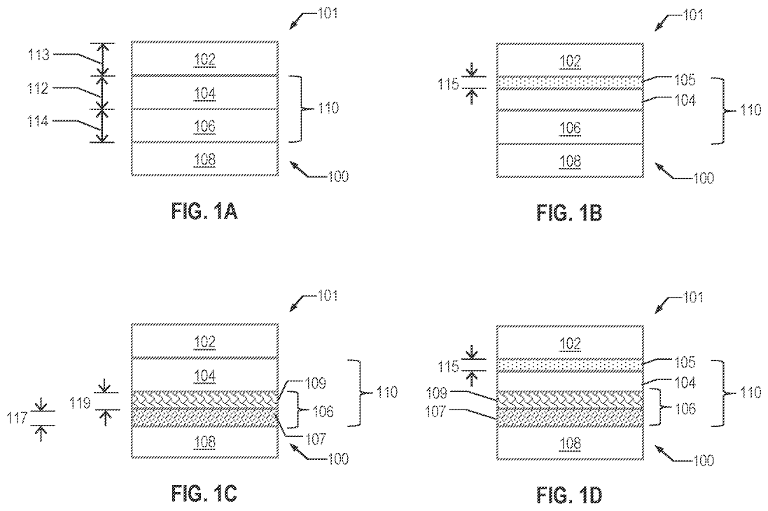

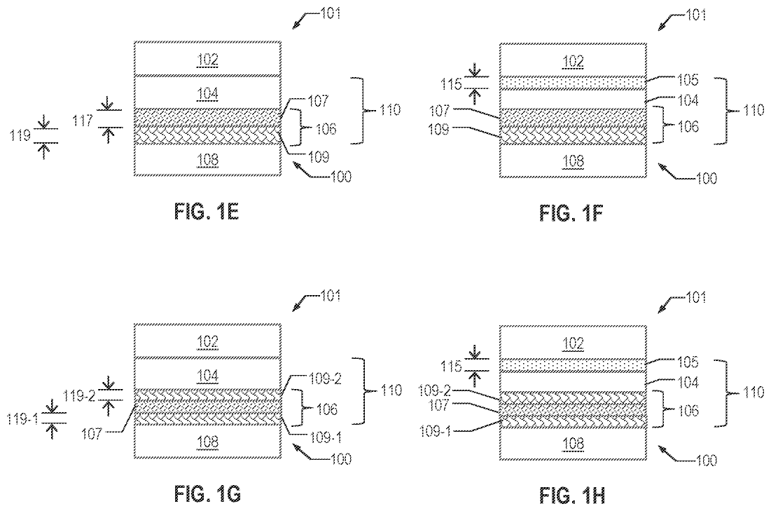

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, analogous elements designated in the present drawings with different reference numerals after a dash, e.g., interface layers 104-1, 104-2, and so on may be referred to together without the reference numerals after the dash, e.g., as “interface layers 104.” To not clutter the drawings, if multiple instances of certain elements are illustrated, only some of the elements may be labeled with a reference sign. A plurality of drawings with the same number and different letters may be referred to without the letters, e.g., FIGS. 1A-1H may be referred to as “FIG. 1.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross section of a device to detect the shape and the location of various device elements described herein using, e.g., Physical Failure Analysis (PFA) would allow determination of presence of IC devices implementing transistor gate stacks with thick hysteretic elements as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices implementing transistor gate stacks with thick hysteretic elements as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

FIGS. 1A-1H are cross-sectional side views a transistor gate-channel arrangement 101 including a channel material 102 and a transistor gate stack 100 (also referred to as a “gate stack 100” herein), in accordance with various embodiments. The transistor gate stack 100 may include a gate electrode material 108, and a multilayer gate insulator 110 disposed between the gate electrode material 108 and the channel material 102.

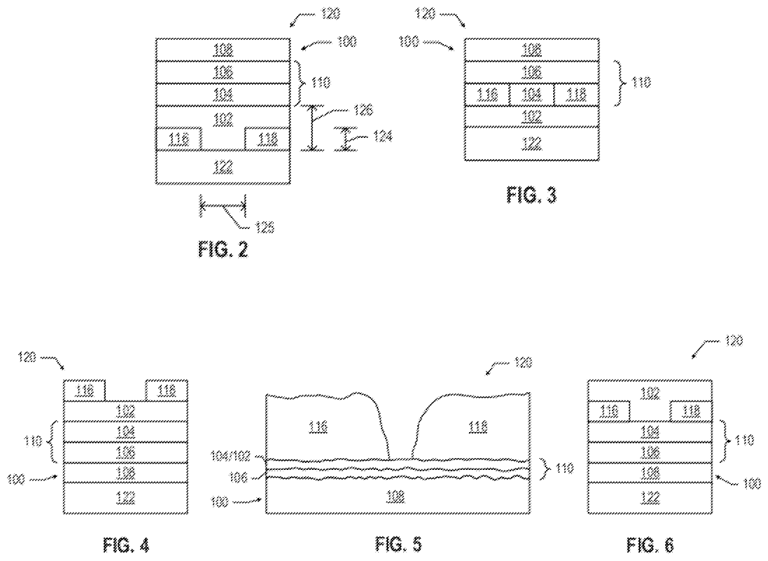

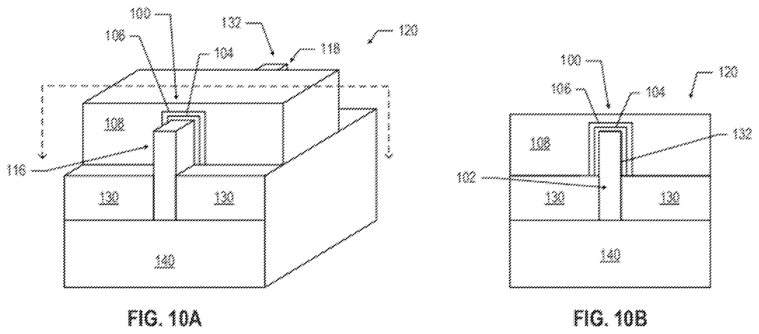

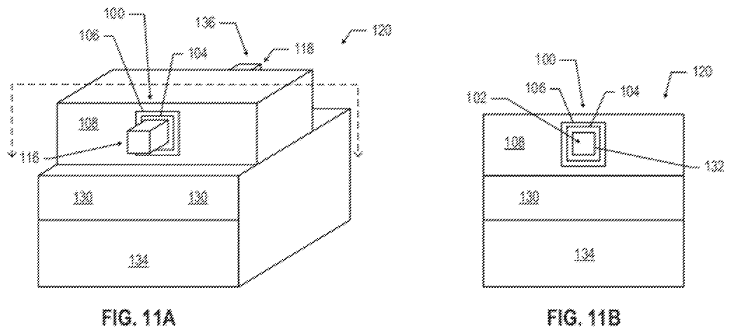

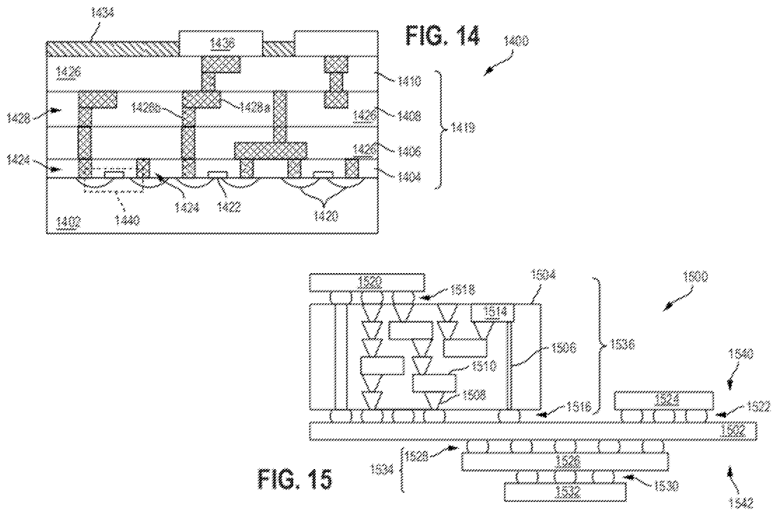

Implementations of the present disclosure may be formed or carried out on any suitable support structure, such as a substrate, a die, a wafer, or a chip. In particular, the transistor gate-channel arrangement 101 may be provided over any suitable support structure. Such a support structure is not shown in FIG. 1 but is shown, e.g., in FIGS. 2-4 and FIGS. 6-9 as a support structure 122, in FIGS. 10A and 10B as a support structure 140, in FIGS. 11A and 11B as a support structure 134, and in FIG. 14 as a support structure 1402. The support structure may, e.g., be the wafer 1300 of FIG. 13, discussed below, and may be, or be included in, a die, e.g., the singulated die 1302 of FIG. 13, discussed below. The support structure may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure may be a printed circuit board (PCB) substrate. Although a few examples of materials from which the support structure may be formed are described here, any material that may serve as a foundation upon which an IC device implementing one or more transistor gate stacks with thick hysteretic elements as described herein may be built falls within the spirit and scope of the present disclosure.

In general, the channel material 102 may be composed of semiconductor material systems including, for example, N-type or P-type materials systems. In some embodiments, the channel material 102 may include a substantially monocrystalline semiconductor, such as silicon (Si) or germanium (Ge). In some embodiments, the channel material 102 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material 102 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 102 may include a combination of semiconductor materials.

For some example N-type transistor embodiments (i.e., for the embodiments where the transistor in which the gate stack 100 is included is an N-type metal-oxide-semiconductor (NMOS) transistor), the channel material 102 may include a III-V material having a relatively high electron mobility, such as, but not limited to InGaAs, InP, InSb, and InAs. For some such embodiments, the channel material 102 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor in which the gate stack 100 is included is a P-type metal-oxide-semiconductor (PMOS) transistor), the channel material 102 may advantageously be a group IV material having a high hole mobility, such as, but not limited to Ge or a Ge-rich SiGe alloy. For some example embodiments, the channel material 102 may have a Ge content between 0.6 and 0.9, and advantageously may be at least 0.7.

In some embodiments, the channel material 102 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 102 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel material 102 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, the transistor in which the gate stack 100 is included may be a thin-film transistor (TFT). A TFT is a special kind of a field-effect transistor (FET) made by depositing a thin film of an active semiconductor material, as well as a dielectric layer (e.g., the multilayer gate insulator 110) and a gate electrode (e.g., the gate electrode material 108), over a support (e.g., a support structure as described above) that may be a non-conducting support. Some such materials may be deposited at relatively low temperatures, which allows depositing them within the thermal budgets imposed on back-end fabrication to avoid damaging the front end components such as the logic devices of an IC device in which the gate stack 100 may be included. At least a portion of the active semiconductor material forms a channel of the TFT. In some such embodiments, the channel material 102 may be deposited as a thin film and may include any of the oxide semiconductor materials described above.

In other embodiments, instead of being deposited at relatively low temperatures as described above with reference to the TFTs, the channel material 102 may be epitaxially grown in what typically involves relatively high-temperature processing. In such embodiments, the channel material 102 may include any of the semiconductor materials described above, including oxide semiconductor materials. In some such embodiments, the channel material 102 may be epitaxially grown directly on a semiconductor layer of a support structure over which the transistor that includes the gate stack 100 will be fabricated, in a process known as “monolithic integration.” In other such embodiments, the channel material 102 may be epitaxially grown on a semiconductor layer of another support structure and then the epitaxially grown layer of the channel material 102 may be transferred, in a process known as a “layer transfer,” to a support structure of which the transistor that includes the gate stack 100 will be fabricated, in which case the latter support structure may but does not have to include a semiconductor layer prior to the layer transfer. Layer transfer advantageously allows forming non-planar transistors, such as FinFETs or all-around gate transistors such as nanowire or nanoribbon transistors, over support structures or in layers that do not include semiconductor materials (e.g., in the back-end of an IC device). Layer transfer also advantageously allows forming transistors of any architecture (e.g., non-planar or planar transistors) without imposing the negative effects of the relatively high-temperature epitaxial growth process on devices that may already be present over a support structure.

The channel material 102 deposited at relatively low temperatures is typically a polycrystalline, polymorphous, or amorphous semiconductor, or any combination thereof. The channel material 102 epitaxially grown is typically a highly crystalline (e.g., monocrystalline, or single-crystalline) material. Therefore, whether the channel material 102 is deposited at relatively low temperatures or epitaxially grown can be identified by inspecting grain size of the active portions of the channel material 102 (e.g., of the portions of the channel material 102 that form channels of transistors). An average grain size of the channel material 102 being between about 0.5 and 1 millimeters (in which case the material may be polycrystalline) or smaller than about 0.5 millimeter (in which case the material may be polymorphous or amorphous) may be indicative of the channel material 102 having been deposited (e.g., in which case the transistors in which such channel material 102 is included are TFTs). On the other hand, an average grain size of the channel material 102 being equal to or greater than about 1 millimeter (in which case the material may be a single-crystal material) may be indicative of the channel material 102 having been epitaxially grown and included in the final device either by monolithic integration or by layer transfer.

The channel material 102 may have a thickness 113. In some embodiments, the thickness 113 may be between about 5 and 75 nanometers, including all values and ranges therein, e.g., between about 5 and 50 nanometers or between about 5 and 30 nanometers.

The gate electrode material 108 may include at least one P-type work function metal or N-type work function metal, depending on whether the transistor gate stack 100 is to be included in a PMOS transistor or an NMOS transistor. For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further metal layers may be included for other purposes, such as to act as a barrier layer.

As shown in FIG. 1, the multilayer gate insulator 110 includes a hysteretic element 106 and an interface layer 104, arranged in the gate stack 100 so that the interface layer 104 is disposed between the hysteretic element 106 and the channel material 102, and the hysteretic element 106 is disposed between the interface layer 104 and the gate electrode material 108. In some embodiments, the hysteretic element 106 may be in contact with the gate electrode material 108, as shown in FIG. 1. In some embodiments, the hysteretic element 106 may be in contact with the interface layer 104, as also shown in FIG. 1.

The interface layer 104 may include any material that is electrically thinner than conventional gate dielectrics used in transistor gates. To that end, in some embodiments, the interface layer 104 may be a high-k dielectric with the k-value of at least 20; in other embodiments, the interface layer 104 may be a dielectric having a thickness 112 that is smaller than about 3 nanometers, e.g., smaller than about 2 nanometers or smaller than about 1 nanometer (e.g., be a single atomic monolayer or may include just a few atomic monolayers); and, in still other embodiments, the interface layer 104 may be both a high-k dielectric with the k-value of at least 20 and have a thickness 112 that is smaller than about 1-3 nanometers. Particular choice of a material for the interface layer 104 may depend on other design factors, such as the choice of the channel material 102 (e.g., for the embodiments where the interface layer 104 is in contact with the channel material 102, the channel material 102 and the material of the interface layer 104 may be selected as to form an interface that would have a limited number of defects as to not compromise performance of the transistor) and/or manufacturing processes available (e.g., some manufacturing processes may be particularly suitable for providing dielectric materials with the k-value greater than 20 but not necessarily for providing dielectric materials that have a thickness smaller than about 3 nanometers, while other manufacturing processes may be particularly suitable for providing dielectric materials that have a thickness smaller than about 3 nanometers but not necessarily for providing dielectric materials with the k-value greater than 20). In some embodiments, the interface layer 104 may include silicon and oxygen, e.g., silica. In some embodiments, the interface layer 104 may include oxygen and one or more rare-earth elements (e.g., the interface layer 104 may include one or more rare-earth metal oxides such as yttrium oxide, lanthanum oxide, etc.). In some embodiments, the interface layer 104 may include a metal (e.g., hafnium, zirconium, lanthanum, aluminum, tantalum, etc.) and oxygen, e.g., be a metal oxide. In some embodiments, the interface layer 104 may include a two-dimensional (2D) material, i.e., a material with a thickness of a few nanometers or less, where electrons in the material are free to move in the 2D plane but their restricted motion in the third direction is governed by quantum mechanics. In some such embodiments, the interface layer 104 may include a single atomic monolayer of a 2D material, while, in other such embodiments, the interface layer 104 may include five or fewer (e.g., three or fewer) atomic monolayers of a 2D material. Examples of 2D materials that may be used to implement the interface layer 104 include, but are not limited to, graphene, boron disulfide, or a metal chalcogenide. In some embodiments where the interface layer 104 includes a metal chalcogenide, a metal chalcogenide a transition metal or a post-transition metal, and the metal atom is not limited to 4+ oxidation states. A 2D material included in the interface layer 104 may include other materials, such as indium and selenium (e.g., in the form of indium selenide). In the embodiments where a metal chalcogenide is included in the interface layer 104, the metal chalcogenide may be a transition metal dichalcogenide (TMD). A TMD may include a transition metal, such as tungsten, molybdenum, niobium, tantalum, zirconium, hafnium, gallium, manganese, vanadium, or rhenium, and a chalcogen, such as sulfur, selenium, or tellurium. Some TMDs that may be included in the interface layer 104 may include niobium and sulfur (e.g., in the form of niobium disulfide), tungsten and selenium (e.g., in the form of tungsten diselenide), molybdenum and sulfur (e.g., in the form of molybdenum sulfide), and molybdenum and tellurium (e.g., in the form of molybdenum telluride), but these are simply examples, and any suitable TMD or other metal chalcogenide may be used.

In some embodiments, the interface layer 104 may be formed using a low-temperature deposition process, such as physical vapor deposition (PVD) (e.g., sputtering), atomic layer deposition (ALD), or chemical vapor deposition (CVD). The ability to deposit the interface layer 104 at temperatures low enough to be compatible with back-end manufacturing processes represents a particular advantage. The interface layer 104 may be deposited on sidewalls or conformably on any desired structure to a precise thickness, allowing the manufacture of transistors having any desired geometry. Additionally, deposition of the interface layer 104 may be compatible with deposition of many materials that may act as the hysteretic element 106 (e.g., FE/AFE hafnium oxide).

The use of the interface layer 104 in the multilayer gate insulator 110 may advantageously increase the gate field at or near an interface between the channel material 102 and the hysteretic element 106, which, in turn, may help maintain carrier mobility in short-channel devices and, therefore, ensure adequate transistor performance in terms of, e.g., gate leakage, carrier mobility, and subthreshold swing even when the hysteretic element 106 is a thick hysteretic element. Consequently, the use of the interface layer 104 in the multilayer gate insulator 110 may advantageously allow increasing the overall thickness of the multilayer gate insulator 110, expand the list of hysteretic elements that may be used in the multilayer gate insulator 110, and/or may allow using hysteretic elements with suboptimal properties while reducing the negative consequences, such as gate leakage, on transistor performance.

In some embodiments, the hysteretic element 106 may have a thickness 114 that is at least 10-15 nanometers, e.g., at least about 25 nanometers, at least about 50 nanometers, e.g., between about 55 and 110 nanometers or between about 50 and 100 nanometers. The ability to have such a thick hysteretic element in the multilayer gate insulator 110, due to the inclusion of the interface layer 104, opens the possibilities for wider use of hysteretic materials in arrangements. In some embodiments, the hysteretic element 106 may include a layer of a hysteretic material, as shown in FIG. 1A and FIG. 1B, e.g., a layer of a FE or an AFE material. Such an FE/AFE material may include one or more materials that can exhibit sufficient FE/AFE behavior, such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure enough of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). Thus, in some embodiments, the hysteretic material of the hysteretic element 106 may include hafnium, oxygen, and one or more dopants, wherein the one or more dopants include one or more of zirconium, yttrium, silicon, germanium, aluminum, etc. More generally, the hysteretic material of the hysteretic element 106 may include a metal (e.g., hafnium, zirconium, lanthanum, aluminum, tantalum, etc.) and oxygen, possibly with one or more dopants, wherein the one or more dopants include one or more of zirconium, yttrium, silicon, germanium, aluminum, etc. In some embodiments, the hysteretic material of the hysteretic element 106 may include oxygen and one or more rare-earth elements (e.g., the interface layer may include one or more rare-earth oxides such as yttrium oxide, lanthanum oxide, etc.). In some embodiments, the hysteretic element 106 may be deposited to include increased amounts of nitrogen (e.g., using plasma processing, nitrogen implants, or nitrogen annealing), which would result in the hysteretic element 106 including nitrogen in concentration of at least about 10¹⁶ nitrogen atoms per cubic centimeter, e.g., in concentration between about 10¹⁶ nitrogen atoms per cubic centimeter and about 10²⁰ nitrogen atoms per cubic centimeter. However, in other embodiments, any other materials which exhibit FE/AFE behavior at thin dimensions may be used as the hysteretic element and are within the scope of the present disclosure

In some embodiments, the interface layer 104 may be in contact with the channel material 102, as shown in FIG. 1A, FIG. 1C, FIG. 1E, and FIG. 1G, and may provide the interface between the channel material 102 and the remainder of the multilayer gate insulator 110. In other embodiments, an additional interface layer 105 may be present between the interface layer 104 and the channel material 102, as shown in FIG. 1B, FIG. 1D, FIG. 1F, and FIG. 1H, where the interface layer 104 may be in contact with the additional interface layer 105 and the additional interface layer 105 may be in contact with the channel material 102. In some embodiments, such an additional interface layer 105 may include a hysteretic material, e.g., any of the hysteretic materials described with reference to the hysteretic element 106, but be much thinner than the hysteretic material of the hysteretic element 106. For example, in some embodiments, the additional interface layer 105 may have a thickness 115 that is smaller than about 3 nanometers, e.g., the thickness 115 may be between about 0.5 and 3 nanometers. Similar to the hysteretic element 106, in some embodiments, the additional interface layer 105 may be deposited so as to include increased amounts of nitrogen (e.g., using plasma processing, nitrogen implants, or nitrogen annealing), which would result in the additional interface layer 105 including nitrogen in concentration of at least about 101⁶ nitrogen atoms per cubic centimeter, e.g., in concentration between about 10¹⁶ nitrogen atoms per cubic centimeter and about 10²⁰ nitrogen atoms per cubic centimeter. In other embodiments, the additional interface layer 105 may include any material (e.g., a semiconductor material) capable of forming a relatively defect-free interface with the channel material 102. Providing a thin layer of the additional interface layer 105 between the channel material 102 and the interface layer 104 may result in a better interface with the channel material 102 (e.g., less defects at the interface) than what can be achievable if the interface layer 104 directly interfaces with the channel material 102. Even if the additional interface layer 105 is a hysteretic material, because it's thickness 115 is less than about 3, it is the hysteretic element 106 that is designed to provide hysteretic functionality to the transistor, and the additional interface layer 105 may merely be included for the purpose of providing a better interface with the channel material 102.

In further embodiments, the hysteretic element 106 may be a stack of alternating layers of materials that can trap charges. In some such embodiments, the stack may be a two-layer stack, as shown in FIGS. 1C-1F, while in other such embodiments, the stack may be a three-layer stack, as shown in FIGS. 1G-1H.

If the hysteretic element 106 is a two-layer stack, it may include a first layer 107 that is a charge-trapping layer and a second layer 109 that is a tunnelling layer. Such a first layer 107 may include a sub-stoichiometric material (i.e., a material that includes less than a stochiometric amount of a reagent), while such a second layer 109 may include an insulator material. The insulator material of the second layer 109 may include silicon and oxygen (e.g., silicon oxide), or any other suitable insulator. The sub-stoichiometric material of the first layer 107 may include vacancies in concentration of at least about 10¹⁸ vacancies per cubic centimeter, e.g., in concentration between about 10¹⁸ vacancies per cubic centimeter and about 10²²-10²³ vacancies per cubic centimeter. As known in the art, vacancies refer to cites where atoms (e.g., oxygen or nitrogen) that should be present are missing, thus providing a defect in a material. For example, the sub-stoichiometric material of the first layer 107 may include oxygen and the vacancies in the first layer 107 may be oxygen vacancies, or the sub-stoichiometric material of the first layer 107 may include nitrogen and the vacancies in the first layer 107 may be nitrogen vacancies. During operation, charges may be trapped in the vacancies of the first layer 107, thus the vacancies is one way to provide a charge-trapping layer of a hysteretic arrangement. In general, any material that has defects that can trap charge may be used in/as a charge-trapping layer, e.g., as the first layer 107 of the multilayer gate insulator 110. Such defects are very detrimental to operation of logic devices and, therefore, typically, deliberate steps need to be taken to avoid presence of the defects. However, for memory devices, such defects are desirable because charge-trapping may be used to represent different memory states of a memory cell. In various embodiments, the charge-trapping material of the first layer 107 may include an electrically conductive material such as a metal, or a semiconductor material. In some embodiments, the charge-trapping material of the first layer 107 may include a material that includes silicon and nitrogen (e.g., silicon nitride).

In various embodiments, the first layer 107 and the second layer 109 may be arranged in different manners. For example, in some embodiments, the first layer 107 may be between (e.g., in contact with each of) the gate electrode material 108 and the second layer 109, and the second layer 109 may be between (e.g., in contact with each of) the first layer 107 and the interface layer 104, as is shown in FIG. 1C and FIG. 1D, i.e., the second layer 109 may be closer to the interface layer 104 and, therefore, to the channel material 102, than the first layer 107, while the first layer 107 may be closer to the gate electrode material 108 than the second layer 109. Such embodiments may be particularly advantageous for NMOS transistors (i.e., for transistors with the channel material 102 being an N-type semiconductor material), because, in such devices, electrons travel from the channel material 102 through the second layer 109 to the first layer 107 (where charges are trapped) and, finally, to the gate electrode material 108. In other embodiments, the first layer 107 may be between (e.g., in contact with each of) the interface layer 104 and the second layer 109, and the second layer 109 may be between (e.g., in contact with each of) the first layer 107 and the gate electrode material 108, as is shown in FIG. 1E and FIG. 1F, i.e., the first layer 107 may be closer to the interface layer 104 and, therefore, to the channel material 102, than the second layer 109, while the second layer 109 may be closer to the gate electrode material 108 than the first layer 107. Such embodiments may be particularly advantageous for PMOS transistors (i.e., for transistors with the channel material 102 being a P-type semiconductor material), because in such devices electrons travel from the gate electrode material 108, through the second layer 109, to the first layer 107 (where charges are trapped) and, finally, to the channel material 102. Although not specifically shown in the present drawings, in some embodiments, the hysteretic element 106 may include multiple pairs of the first layer 107 and the second layer 109, e.g., a stack of the first layer 107 and the second layer 109 (e.g., multiple pairs of the first layer 107 and the second layer 109 arranged as shown in FIG. 1C and FIG. 1D, or multiple pairs of the first layer 107 and the second layer 109 arranged as shown in FIG. 1E and FIG. 1F). In some embodiments, a thickness 117 of the first layer 107 may be between about 0.5 and 10 nanometers, although, in other embodiments the thickness 117 may be greater than 10 nanometers, thus increasing the capacity for the first layer 107 to trap charges. In some embodiments, a thickness 119 of the second layer 109 may be between about 0.5 and 10 nanometers, e.g., between about 0.5 and 5 nanometers. In some embodiments, a total thickness of the hysteretic element 106 provided as a stack of alternating layers of materials that can trap charges (i.e., a hysteretic arrangement) may be the thickness 114 as described above.

If the hysteretic element 106 is a three-layer stack, it may include a first layer 107 that is a charge-trapping layer, sandwiched between two second layers 109, as shown in FIG. 1G and FIG. 1H, illustrating the first layer 107 being between (e.g., be in contact with each of) a layer 109-1 and a layer 109-2. In such embodiments, the first layer 107 may be a charge-trapping layer as described above, while each of the layers 109 may be a layer of an insulator material as described above, where one of the layers 109-1 and 109-2 is a tunnelling layer and another one of the layers 109-1 and 109-2 is a field layer. In some embodiment of the hysteretic element 106 being a three-layer stack, thicknesses 119-1 and 119-2 of the layers 109-1 and 109-2 of the insulator material may be between about 0.5 and 5 nanometers, while the thickness 117 of the charge-trapping layer (i.e., the first layer 107) may be between at least about 10 nanometers. For the embodiments where the hysteretic element 106 is a three-layer stack, a total thickness of the hysteretic element 106 may be the thickness 114 as described above.

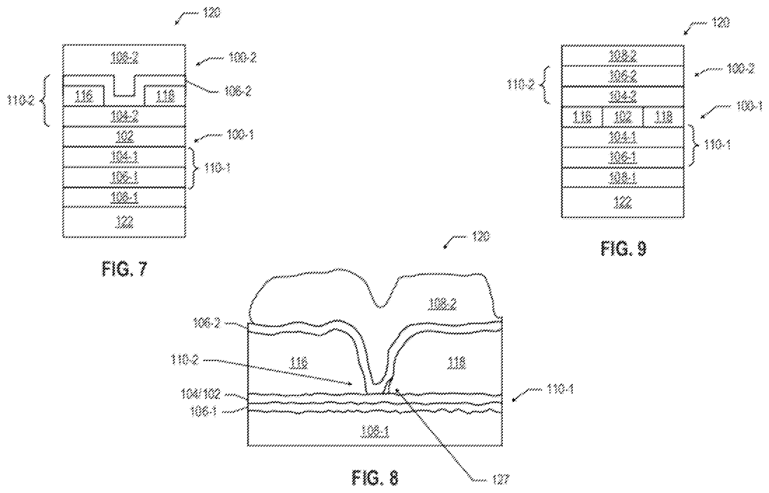

The transistor gate stack 100 may be included in any suitable transistor structure. For example, FIGS. 2-6 are cross-sectional side views of example single-gate transistors 120 including a transistor gate stack 100, FIGS. 7-9 are cross-sectional side views of example double-gate transistors 120 including a transistor gate stack 100, FIGS. 10A and 10B are perspective and cross-sectional side views, respectively, of an example FinFET 120 including a transistor gate stack, and FIGS. 11A and 11B are perspective and cross-sectional side views, respectively, of an example all-around gate transistor 120 including a transistor gate stack, in accordance with various embodiments. The transistors 120 illustrated in FIGS. 2-11 do not represent an exhaustive set of transistor structures in which a gate stack 100 may be included, but that may provide examples of such structures. Although particular arrangements of materials are discussed below with reference to FIGS. 2-11, intermediate materials may be included in the gate stacks 100 of the transistors 120 as discussed above with reference to FIGS. 1A-1H. For example, although FIGS. 2-11 do not show the layers 107 and 109 as shown in FIGS. 1C-1H, the hysteretic element 106 of any of the transistors 120 of FIGS. 2-11 may include such charge-trapping hysteretic arrangements. In another example, although FIGS. 2-11 do not show an additional interface layer 105 as shown in FIG. 1B, FIG. 1D, FIG. 1F, and FIG. 1H, such an additional interface layer 105 may be includes between the interface layer 106 and the channel material 102 of any of the transistors 120 of FIGS. 2-11. Note that FIGS. 2-11 are intended to show relative arrangements of the components therein, and that transistors 120 may include other components that are not illustrated (e.g., electrical contacts to the source region 116 and the drain region 118 to transport current in and out of the transistors 120). Any of the components of the transistors 120 discussed below with reference to FIGS. 2-11 may take the form of any of the embodiments of those components discussed above with reference to FIG. 1. Additionally, although various components of the transistors 120 are illustrated in FIGS. 2-11 as being planar rectangles or formed of rectangular solids, this is simply for ease of illustration, and embodiments of these transistors 120 may be curved, rounded, or otherwise irregularly shaped as dictated by the manufacturing processes used to fabricate the transistors 120.

FIG. 2 depicts a transistor 120 including a transistor gate stack 100 and having a single “top” gate provided by the gate electrode material 108 and the multilayer gate insulator 110 (which includes the hysteretic element 106 and the interface layer 104 as described herein). The multilayer gate insulator 110 may be disposed between the gate electrode material 108 and the channel material 102. The multilayer gate insulator 110 may border the channel material 102; in particular, the interface layer 104 may contact the channel material 102 without any intervening material. In the embodiment of FIG. 2, the gate stack 100 is shown as disposed on a support structure 122. The support structure 122 may be any structure on which the gate stack 100, or other elements of the transistor 120, is disposed, e.g., any of the support structures described above. In some embodiments, the support structure 122 may include a semiconductor, such as silicon. In some embodiments, the support structure 122 may include an insulating layer, such as an oxide isolation layer. For example, in the embodiments of FIGS. 2 and 3, the support structure 122 may include a semiconductor material and an interface layer dielectric (ILD) disposed between the semiconductor material and the source region 116, the channel material 102, and the drain region 118, to electrically isolate the semiconductor material of the support structure 122 from the source region 116, the channel material 102, and the drain region 118 (and thereby mitigate the likelihood that a conductive pathway will form between the source region 116 and the drain region 118 through the support structure 122). Examples of ILDs that may be included in a support structure 122 in some embodiments may include silicon oxide, silicon nitride, aluminum oxide, and/or silicon oxynitride. Any suitable ones of the embodiments of the support structure 122 described with reference to FIG. 2 may be used for the support structures 122 of others of the transistors 102 disclosed herein.

As noted above, the transistor 120 may include a source region 116 and a drain region 118 disposed on the support structure 122, with the channel material 102 disposed between the source region 116 and the drain region 118 so that at least some of the channel material 102 is coplanar with at least some of the source region 116 and the drain region 118. The source region 116 and the drain region 118 may have a thickness 124, and the channel material 102 may have a thickness 126. The thickness 126 may take the form of any of the embodiments of the thickness 113 discussed above with reference to FIG. 1. In some embodiments, the thickness 124 may be less than the thickness 126 (as illustrated in FIG. 2, with the source region 116 and the drain region 118 each disposed between some of the channel material 102 and the support structure 122), while in other embodiments, the thickness 124 may be equal to the thickness 126. In some embodiments, the channel material 102, the interface layer 104, the hysteretic element 106, and/or the gate electrode material 108 may conform around the source region 116 and/or the drain region 118. The source region 116 and the drain region 118 may be spaced apart by a distance 125 that is the gate length of the transistor 120. In some embodiments, the gate length may be between 10 and 30 nanometers (e.g., between 12 and 20 nanometers, or approximately 25 nanometers).

The source region 116 and the drain region 118 may be formed using any suitable processes known in the art. For example, the source region 116 and the drain region 118 may generally be formed using either an implantation/diffusion process or an etching/deposition process. In the former process, dopants such as boron, aluminum, antimony, phosphorous, or arsenic may be ion-implanted into the channel material to form the source region 116 and the drain region 118. An annealing process that activates the dopants and causes them to diffuse further into the channel material 102 typically follows the ion implantation process. In the latter process, the channel material 102 may first be etched to form recesses at the locations of the source region 116 and the drain region 118. An epitaxial deposition process may then be carried out to fill the recesses with material that is used to fabricate the source region 116 and the drain region 118. In some implementations, the source region 116 and the drain region 118 may be fabricated using a silicon alloy such as silicon germanium or silicon carbide. In some implementations, the epitaxially deposited silicon alloy may be doped in situ with dopants such as boron, arsenic, or phosphorous. In further embodiments, the source region 116 and the drain region 118 may be formed using one or more alternate semiconductor materials such as germanium or a group III-V material or alloy. And in further embodiments, one or more layers of metal and/or metal alloys may be used to form the source region 116 and the drain region 118. Any suitable ones of the embodiments of the source region 116 and the drain region 118 described above may be used for any of the source regions 116 and drain regions 118 described herein.

FIG. 3 depicts a transistor 120 including a transistor gate stack 100 and having a single “top” gate provided by the gate electrode material 108 and the multilayer gate insulator 110 (which includes the hysteretic element 106 and the interface layer 104). The multilayer gate insulator 110 may be disposed between the gate electrode material 108 and the channel material 102. The multilayer gate insulator 110 may border the channel material 102; in particular, the interface layer 104 may contact the channel material 102 without any intervening material. In the embodiment of FIG. 3, the gate stack 100 is shown as disposed on a support structure 122. The transistor 120 may include a source region 116 and a drain region 118 disposed on the support structure 122, with the interface layer 104 disposed between the source region 116 and the drain region 118 so that at least some of the interface layer 104 is coplanar with at least some of the source region 116 and the drain region 118. As discussed above, in some embodiments, the support structure 122 of FIG. 3 may include a semiconductor material and ILD disposed between the semiconductor material and the source region 116, the channel material 102, and the drain region 118, to electrically isolate the semiconductor material of the support structure 122 from the source region 116, the channel material 102, and the drain region 118. In some embodiments, the interface layer 104, the hysteretic element 106, and/or the gate electrode material 108 may conform around the source region 116 and/or the drain region 118.

FIG. 4 depicts a transistor 120 including a transistor gate stack 100 and having a single “bottom” gate provided by the gate electrode material 108 and the multilayer gate insulator 110 (which includes the hysteretic element 106 and the interface layer 104). The multilayer gate insulator 110 may be disposed between the gate electrode material 108 and the channel material 102. The multilayer gate insulator 110 may border the channel material 102; in particular, the interface layer 104 may contact the channel material 102 without any intervening material. In the embodiment of FIG. 4, the gate stack 100 is shown as disposed on a support structure 122 in an orientation “upside down” to the one illustrated in FIG. 2; that is, the gate electrode material 108 may be disposed between the support structure 122 and the channel material 102. The transistor 120 may include a source region 116 and a drain region 118 disposed on the channel material 102 such that the source region 116 and the drain region 118 are not coplanar with the channel material 102.

FIG. 5 depicts a transistor 120 having the structure of the transistor 120 of FIG. 4. In particular, the transistor 120 of FIG. 5 includes a transistor gate stack 100 and has a single “bottom” gate provided by the gate electrode material 108 and the multilayer gate insulator 110 (which includes the hysteretic element 106 and the interface layer 104). In the embodiment of FIG. 5, the interface layer 104 provides the channel material 102, so the channel material 102 is not separately labeled. The transistor 120 of FIG. 5 may also include a support structure 122 (not shown) arranged so that the gate electrode material 108 is disposed between the support structure 122 and the multilayer gate insulator 110. The transistor 120 may include a source region 116 and a drain region 118 disposed on the channel 102 such that the source region 116 and the drain region 118 are not coplanar with the channel material 102. In the embodiment depicted in FIG. 5, the source region 116 and the drain region 118 may be deposited on the interface layer 104. Any suitable materials may be used to form the transistor 120 of FIG. 5, as discussed above. For example, the gate electrode material 108 may be titanium nitride, the hysteretic element 106 may be hysteretic (e.g., FE/AFE) hafnium oxide or any other hysteretic materials or hysteretic arrangements as described herein, and the source region 116 and the drain region 118 may be formed of aluminum. The gate length of the transistor 120 of FIG. 5 may be in the ranges described above, e.g., approximately 12-25 nanometers.

FIG. 6 depicts a transistor 120 including a transistor gate stack 100 and having a single “bottom” gate provided by the gate electrode material 108 and the multilayer gate insulator 110 (which includes the hysteretic element 106 and the interface layer 104). The multilayer gate insulator 110 may be disposed between the gate electrode material 108 and the channel material 102. The multilayer gate insulator 110 may border the channel material 102; in particular, the interface layer 104 may contact the channel material 102 without any intervening material. In the embodiment of FIG. 6, the gate stack 100 is shown as disposed on a support structure 122 in an orientation “upside down” to the one illustrated in FIG. 2; that is, the gate electrode material 108 may be disposed between the support structure 122 and the channel material 102. The transistor 120 may include a source region 116 and a drain region 118 disposed on the channel material 102 such that at least some of the source region 116 and at least some of the drain region 118 are coplanar with at least some of the channel material 102. In some embodiments, the source region 116 and the drain region 118 may each be disposed between some of the channel material 102 and the support structure 122, as illustrated in FIG. 6, while in other embodiments, the channel material 102 may not extend “above” the source region 116 or the drain region 118. In some embodiments, the channel material 102 may conform around the source region 116 and/or the drain region 118.

FIG. 7 depicts a double-gate transistor 120 including two transistor gate stacks 100-1 and 100-2 and having “bottom” and “top” gates provided by the gate electrode material 108-1/multilayer gate insulator 110-1 and the gate electrode material 108-2/multilayer gate insulator 110-2, respectively. The multilayer gate insulators 110-1 and 110-2 may include hysteretic elements 106-1 and 106-2, and interface layers 104-1 and 104-2, respectively. Each multilayer gate insulator 110 may be disposed between the corresponding gate electrode material 108 and the channel material 102. Each multilayer gate insulator 110 may border the channel material 102; in particular, in some embodiments, the interface layers 104-1 and 104-2 may contact the channel material 102 without any intervening materials, while, in other embodiments, an additional interface layer 105 may be present between the interface layer 104-1 and the channel material 102 and/or between the interface layer 104-2 and the channel material 102. The transistor 120 may include a source region 116 and a drain region 118 disposed proximate to the channel material 102. In the embodiment illustrated in FIG. 7, the source region 116 and the drain region 118 are disposed on the interface layer 104-2, and the hysteretic element 106-2 is disposed conformably around the source region 116, the interface layer 104-2, and the drain region 118. The gate electrode material 108-2 is disposed on the hysteretic element 106-2. In the embodiment of FIG. 7, at least some of the source region 116 and at least some of the drain region 118 are coplanar with at least some of the hysteretic element 106-2.

FIG. 8 depicts a double-gate transistor 120 having the structure of the transistor 120 of FIG. 7. In particular, the transistor 120 of FIG. 8 includes two transistor gate stacks 100-1 and 100-2 and having “bottom” and “top” gates provided by the gate electrode material 108-1/multilayer gate insulator 110-1 and the gate electrode material 108-2/multilayer gate insulator 110-2, respectively. In the embodiment of FIG. 8, a continuous region provides the interface layer 104-1, the channel material 102, and the interface layer 104-2. The transistor 120 of FIG. 8 may also include a support structure 122 (not shown) arranged so that the gate electrode material 108-1 is disposed between the support structure 122 and the multilayer gate insulator 110. The transistor 120 may include a source region 116 and a drain region 118 disposed on the channel material 102 such that the source region 116 and the drain region 118 are not coplanar with the channel material 102. In the embodiment depicted in FIG. 8, the source region 116 and the drain region 118 may be deposited on the interface layer 104. During manufacture, a void 127 may be formed between the hysteretic element 106-2 and the interface layer 104; while such voids 127 may reduce the performance of the transistor 120, the transistor 120 may still function adequately as long as adequate coupling between the hysteretic element 106-2 and the interface layer 104 is achieved. Any suitable materials may be used to form the transistor 120 of FIG. 8, as discussed above. For example, the gate electrode material 108-1 may be titanium nitride, the hysteretic elements 106-1 and 106-2 may be any of the hysteretic materials and/or arrangements described herein, the source region 116 and the drain region 118 may be formed of aluminum, and the gate electrode material 108-2 may be palladium. The gate length of the transistor 120 of FIG. 8 may be in the ranges described above, e.g., approximately 12-25 nanometers.

FIG. 9 depicts a double-gate transistor 120 including two transistor gate stacks 100-1 and 100-2 and having “bottom” and “top” gates provided by the gate electrode material 108-1/multilayer gate insulator 110-1 and the gate electrode material 108-2/multilayer gate insulator 110-2, respectively. Each multilayer gate insulator 110 may include a hysteretic element 106 and an interface layer 104. Each multilayer gate insulator 110 may be disposed between the corresponding gate electrode material 108 and the channel material 102. Each multilayer gate insulator 110 may border the channel material 102; in particular, the interface layers 104-1 and 104-2 may contact the channel material 102 without any intervening material. The transistor 120 may include a source region 116 and a drain region 118 disposed proximate to the channel material 102. In the embodiment illustrated in FIG. 9, the source region 116 and the drain region 118 are coplanar with the channel material 102 and disposed between the hysteretic elements 106-1 and 106-2. The relative arrangement of the source region 116, the drain region 118, and the channel material 102 may take the form of any of the embodiments discussed above with reference to FIG. 2.

FIGS. 10A and 10B are perspective and cross-sectional side views, respectively, of an example FinFET 120 including a transistor gate stack 100, in accordance with various embodiments. The transistor 120 of FIGS. 10A and 10B may include a channel material 102, and a gate stack 100 including a gate electrode material 108, a hysteretic element 106 and an interface layer 104. The interface layer 104 may be disposed between the hysteretic element 106 and the channel material 102 (e.g., the interface layer 104 may be in contact with the channel material 102). In the FinFET 120 illustrated in FIGS. 10A and 10B, a fin 132 formed of a semiconductor material may extend from a base 140 of the semiconductor material. An insulator material 130, e.g., an oxide material, typically referred to as a “shallow trench insulator” (STI), may be disposed on either side of the fin 132. In some embodiments, the insulator material 130 may include any of the materials discussed herein with reference to the ILD or the second layer 109.

The gate stack 100 may wrap around the fin 132 as shown, with the channel material 102 corresponding to the portion of the fin 132 wrapped by the gate stack 100. In particular, the interface layer 104 may wrap around the channel material 102 of the fin 132, the hysteretic element 106 may wrap around the interface layer 104, and the gate electrode material 108 may wrap around the hysteretic element 106. The fin 132 may include a source region 116 and a drain region 118 on either side of the gate stack 100, as shown. The composition of the channel material 102, the source region 116, and a drain region 118 may take the form of any of the embodiments disclosed herein, or known in the art. Although the fin 132 illustrated in FIGS. 10A and 10B is shown as having a rectangular cross section, the fin 132 may instead have a cross section that is rounded or sloped at the “top” of the fin 132, and the gate stack 100 may conform to this rounded or sloped fin 132. In use, the FinFET 120 may form conducting channels on three “sides” of the fin 132, potentially improving performance relative to single-gate transistors (which may form conducting channels on one “side” of the channel material 102) and double-gate transistors (which may form conducting channels on two “sides” of the channel material 102).

FIGS. 11A and 11B are perspective and cross-sectional side views, respectively, of an example all-around gate transistor 120 including a transistor gate stack 100, in accordance with various embodiments. The transistor 120 of FIGS. 11A and 11B may include a channel material 102, and a gate stack 100 including a gate electrode material 108, a hysteretic element 106 and IGZO 104.

The interface layer 104 may be disposed between the hysteretic element 106 and the channel material 102, as described herein. In the all-around gate transistor 120 illustrated in FIGS. 11A and 11B, an elongated structure 136 formed of a semiconductor material may extend above a support structure 134 and a layer of insulator material 130. The elongated structure 136 may take the form of a nanowire or nanoribbon, for example. The gate stack 100 may wrap entirely or almost entirely around the elongated structure 136, as shown, with the channel material 102 corresponding to the portion of the elongated structure 136 wrapped by the gate stack 100. In particular, the interface layer 104 may wrap around the channel material 102 of the fin 132, the hysteretic element 106 may wrap around the interface layer 104, and the gate electrode material 108 may wrap around the hysteretic element 106. In some embodiments, the gate stack 100 may fully encircle the elongated structure 136. The elongated structure 136 may include a source region 116 and a drain region 118 on either side of the gate stack 100, as shown. The composition of the channel material 102, the source region 116, and a drain region 118 may take the form of any of the embodiments disclosed herein, or known in the art. Although the elongated structure 136 illustrated in FIGS. 11A and 11B is shown as having a substantially square cross section, the elongated structure 136 may instead have a cross section that is rounded or otherwise irregularly shaped, and the gate stack 100 may conform to the shape of the elongated structure 136. In the embodiments where the cross section of the elongated structure 136 is substantially square or circular, a transistor in which the elongated structure 136 is used to provide a channel may be referred to as a “nanowire” transistor. Furthermore, in some embodiments, instead of being substantially square, the cross section of the elongated structure 136 of the FinFET 120 may be substantially rectangular (again, such a substantially rectangular cross section may be rounded or otherwise irregularly shaped), in which case a transistor in which the elongated structure 136 is used to provide a channel may be referred to as a “nanoribbon” transistor. Still further, in some embodiments, the cross section of the elongated structure 136 of the FinFET 120 may be such that the width of the elongated structure 136 (a dimension measured substantially parallel to a plane of the insulator material 130 and a plane of the support structure 134 and substantially perpendicular to the longitudinal axis of the elongated structure 136) may be several times greater than the thickness of the elongated structure 136 (a dimension measured substantially perpendicular to a plane of the insulator material 130 and a plane of the support structure 134), in which case a transistor in which the elongated structure 136 is used to provide a channel may be referred to as a “nanosheet” transistor. In use, the FinFET 120 may form conducting channels on more than three “sides” of the elongated structure 136, potentially improving performance relative to FinFETs. Although FIGS. 11A and 11B depict an embodiment in which the longitudinal axis of the elongated structure 136 runs substantially parallel to a plane of the insulator material 130 (and a plane of the support structure 134), this need not be the case; in other embodiments, for example, the elongated structure 136 may be oriented “vertically” so as to be perpendicular to a plane of the oxide 130 (or plane of the support structure 134).

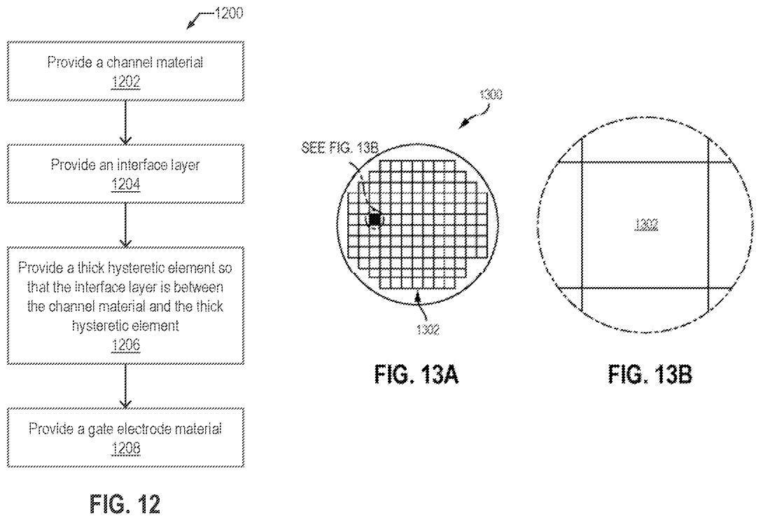

The transistor gate stacks 100 disclosed herein may be manufactured using any suitable techniques. For example, FIG. 12 is a flow diagram of an example method 1200 of manufacturing a transistor gate stack, in accordance with various embodiments. Although the operations of the method 1200 are illustrated once each and in a particular order, the operations may be performed in any suitable order and repeated as desired. For example, one or more operations may be performed in parallel to manufacture multiple transistor gate stacks substantially simultaneously. In another example, the operations may be performed in a different order to reflect the structure of a transistor in which the transistor gate stack will be included.

At 1202, a channel material may be provided. The channel material provided at 1202 may take the form of any of the embodiments of the channel material 102 disclosed herein, for example (e.g., any of the embodiments discussed herein with reference to a transistor 120). The channel material may be provided at 1202 using any suitable deposition and patterning technique known in the art.

At 1204, an interface layer may be provided. The interface layer provided at 1204 may take the form of any of the embodiments of the interface layer 104 disclosed herein, for example. In some embodiments, the interface layer may be provided at 1204 to be in contact with the channel material of 1202. In other embodiments, an additional interface layer may be disposed between the channel material and the interface layer, e.g., the additional interface layer 105 disclosed herein. The interface layer may be provided at 1204 using any suitable technique known in the art. In some embodiments, the interface layer may be provided at 1204 by ALD. In some embodiments, the interface layer may be provided at 1204 by CVD.

At 1206, a thick hysteretic element may be provided such that the interface layer is disposed between the thick hysteretic element and the channel material. The thick hysteretic element provided at 1206 may take the form of any of the embodiments of the hysteretic element 106 disclosed herein. In some embodiments, the thick hysteretic element provided at 1206 may be in contact with the interface layer provided at 1204 (e.g., the interface layer 104 of any of the transistors 120 disclosed herein). The thick hysteretic element may be provided at 1206 using any suitable technique known in the art. In some embodiments, the thick hysteretic element may be provided at 1206 by ALD. In some embodiments, the thick hysteretic element may be provided at 1206 by CVD.

At 1208, a gate electrode material may be provided. The channel material provided at 1202 may take the form of any of the embodiments of the gate electrode material 108 disclosed herein, for example (e.g., any of the embodiments discussed herein with reference to a transistor 120). The gate electrode material may be provided at 1208 using any suitable deposition and patterning technique known in the art.

The method 1200 may further include other manufacturing operations related to fabrication of other components of a transistor 120. For example, the method 1200 may include providing a source region and a drain region (e.g., in accordance with any suitable ones of the embodiments discussed above). In another example, the method 1200 may include providing a source contact/electrode and a drain contact/electrode.

The transistor gate stacks with thick hysteretic elements disclosed herein may be included in any suitable electronic device. FIGS. 13-16 illustrate various examples of apparatuses that may include one or more of the transistor gate stacks with thick hysteretic elements disclosed herein.

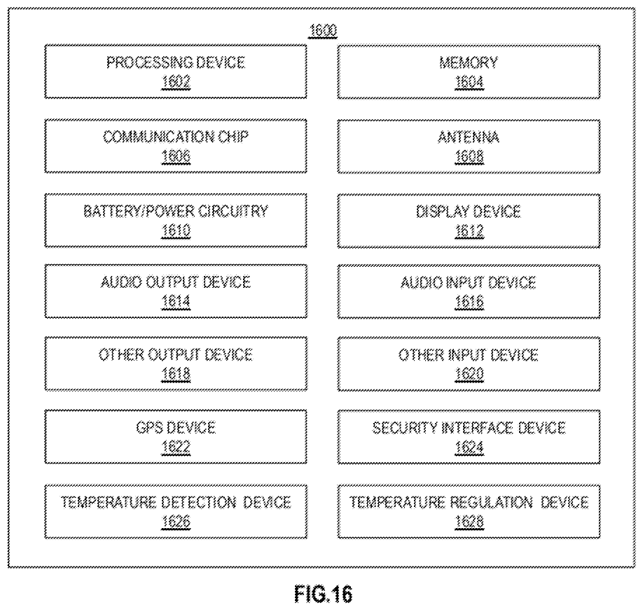

FIGS. 13A and 13B are top views of a wafer 1300 and dies 1302 that may include one or more transistor gate stacks with thick hysteretic elements in accordance with any of the embodiments disclosed herein. The wafer 1300 may be composed of semiconductor material and may include one or more dies 1302 having IC structures formed on a surface of the wafer 1300. Each of the dies 1302 may be a repeating unit of a semiconductor product that includes any suitable IC (e.g., ICs including one or more transistors 120 that include one or more gate stacks 100). After the fabrication of the semiconductor product is complete (e.g., after manufacture of a gate stack 100 in a transistor 120), the wafer 1300 may undergo a singulation process in which each of the dies 1302 is separated from one another to provide discrete “chips” of the semiconductor product. In particular, devices that include a transistor gate stack as disclosed herein may take the form of the wafer 1300 (e.g., not singulated) or the form of the die 1302 (e.g., singulated). The die 1302 may include one or more transistors (e.g., one or more of the transistors 1440 of FIG. 14, discussed below, which may take the form of any of the transistors 120) and/or supporting circuitry to route electrical signals to the transistors, as well as any other IC components. In some embodiments, the wafer 1300 or the die 1302 may include a memory device (e.g., a static random-access memory (SRAM) device), a logic device (e.g., an AND, OR, NAND, or NOR gate), or any other suitable circuit element. Multiple ones of these devices may be combined on a single die 1302. For example, a memory array formed by multiple memory devices may be formed on a same die 1302 as a processing device (e.g., the processing device 1602 of FIG. 16) or other logic that is configured to store information in the memory devices or execute instructions stored in the memory array.

FIG. 14 is a cross-sectional side view of an IC device 1400 that may include one or more transistor gate stacks with thick hysteretic elements in accordance with any of the embodiments disclosed herein. The IC device 1400 may be formed on a support structure 1402 (e.g., the wafer 1300 of FIG. 13A) and may be included in a die (e.g., the die 1302 of FIG. 13B). The support structure 1402 may be a semiconductor substrate composed of semiconductor material systems including, for example, N-type or P-type materials systems. The support structure 1402 may include, for example, a crystalline substrate formed using a bulk silicon or a SOI substructure. In some embodiments, the semiconductor support structure 1402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the support structure 1402. Although a few examples of materials from which the support structure 1402 may be formed are described here, any material that may serve as a foundation for an IC device 1400 may be used. The support structure 1402 may be part of a singulated die (e.g., the dies 1302 of FIG. 13B) or a wafer (e.g., the wafer 1300 of FIG. 13A).

The IC device 1400 may include one or more device layers 1404 disposed on the support structure 1402. The device layer 1404 may include features of one or more transistors 1440 (e.g., metal-oxide-semiconductor field-effect transistors (MOSFETs)) formed on the support structure 1402. The device layer 1404 may include, for example, one or more source and/or drain (S/D) regions 1420, a gate 1422 to control current flow in the transistors 1440 between the S/D regions 1420, and one or more S/D contacts 1424 to route electrical signals to/from the S/D regions 1420. The transistors 1440 may include additional features not depicted for the sake of clarity, such as device isolation regions, gate contacts, and the like. The transistors 1440 are not limited to the type and configuration depicted in FIG. 14 and may include a wide variety of other types and configurations such as, for example, planar transistors, non-planar transistors, or a combination of both. Non-planar transistors may include FinFET transistors, such as double-gate transistors or FinFETs (e.g., as described with reference to FIGS. 10A and 10B), and wrap-around or all-around gate transistors, such as nanoribbon and nanowire transistors (e.g., as described with reference to FIGS. 11A and 11B). In particular, one or more of the transistors 1440 may include one or more transistor gate stacks 100 in accordance with any of the embodiments disclosed herein. For example, a transistor 1440 may take the form of any of the transistors 120 disclosed herein (e.g., any of the single-gate transistors discussed herein with reference to FIGS. 2-6, any of the double-gate transistors discussed herein with reference to FIGS. 7-9, any of the FinFETs discussed herein with reference to FIGS. 10A and 10B, and any of the all-around-gate transistors discussed herein with reference to FIGS. 11A and 11B). The S/D regions 1420 may include the source region 116 and the drain region 118. Transistors 120 including the gate stack 100 may be particularly advantageous when used in the metal layers of a microprocessor device for analog circuitry, logic circuitry, or memory circuitry, and may be formed along with existing CMOS processes.

Each transistor 1440 may include a gate 1422 formed of at least two layers, a gate insulator layer and a gate electrode layer. The gate electrode layer may take the form of any of the embodiments of the gate electrode material 108 disclosed herein. In embodiments in which a transistor 1440 includes one or more transistor gate stacks 100, the gate insulator layer may take the form of any of the embodiments of the multilayer gate insulator 110 disclosed herein and may include an interface layer 104 and a hysteretic element 106.

In some embodiments, when viewed as a cross section of the transistor 1440 along the source-channel-drain direction, the gate electrode may consist of a U-shaped structure that includes a bottom portion substantially parallel to the surface of the substrate and two sidewall portions that are substantially perpendicular to the top surface of the substrate (e.g., as discussed above with reference to the FinFET 120 of FIGS. 10A and 10B). In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers. In some embodiments, the gate electrode may consist of a V-shaped structure (e.g., when the fin 132 does not have a “flat” upper surface, but instead has a rounded peak).

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1420 may be formed within the support structure 1402 adjacent to the gate 1422 of each transistor 1440. The S/D regions 1420 may take the form of any of the embodiments of the source region 116 and the drain region 118 discussed above with reference to the transistors 120. In other embodiments, the S/D regions 1420 may be formed using any suitable processes known in the art. For example, the S/D regions 1420 may be formed using either an implantation/diffusion process or a deposition process. In the former process, dopants such as boron, aluminum, antimony, phosphorous, or arsenic may be ion-implanted into the support structure 1402 to form the S/D regions 1420. An annealing process that activates the dopants and causes them to diffuse farther into the support structure 1402 may follow the ion implantation process. In the latter process, an epitaxial deposition process may provide material that is used to fabricate the S/D regions 1420. In some implementations, the S/D regions 1420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1420 may be formed using one or more alternate semiconductor materials such as germanium or a group III-V material or alloy. In further embodiments, one or more layers of metal and/or metal alloys may be used to form the S/D regions 1420 (e.g., as discussed above with reference to the source region 116 and the drain region 118). In some embodiments, an etch process may be performed before the epitaxial deposition to create recesses in the support structure 1402 in which the material for the S/D regions 1420 is deposited.

Electrical signals, such as power and/or input/output (I/O) signals, may be routed to and/or from the transistors 1440 of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with the interconnect structures 1428 of the interconnect layers 1406-1410. The one or more interconnect layers 1406-1410 may form an interlayer dielectric (ILD) stack 1419 of the IC device 1400.

The interconnect structures 1428 may be arranged within the interconnect layers 1406-1410 to route electrical signals according to a wide variety of designs (in particular, the arrangement is not limited to the configuration of interconnect structures 1428 depicted in FIG. 14). Although a particular number of interconnect layers 1406-1410 is depicted in FIG. 14, embodiments of the present disclosure include IC devices having more or fewer interconnect layers than depicted.

In some embodiments, the interconnect structures 1428 may include trench structures 1428a (sometimes referred to as “lines”) and/or via structures 1428b (sometimes referred to as “holes”) filled with an electrically conductive material such as a metal. The trench structures 1428a may be arranged to route electrical signals in a direction of a plane that is substantially parallel with a surface of the support structure 1402 upon which the device layer 1404 is formed. For example, the trench structures 1428a may route electrical signals in a direction in and out of the page from the perspective of FIG. 14. The via structures 1428b may be arranged to route electrical signals in a direction of a plane that is substantially perpendicular to the surface of the support structure 1402 upon which the device layer 1404 is formed. In some embodiments, the via structures 1428b may electrically couple trench structures 1428a of different interconnect layers 1406-1410 together.

The interconnect layers 1406-1410 may include a dielectric material 1426 disposed between the interconnect structures 1428, as shown in FIG. 14. In some embodiments, the dielectric material 1426 disposed between the interconnect structures 1428 in different ones of the interconnect layers 1406-1410 may have different compositions; in other embodiments, the composition of the dielectric material 1426 between different interconnect layers 1406-1410 may be the same.

A first interconnect layer 1406 (referred to as Metal 1 or “M1”) may be formed directly on the device layer 1404. In some embodiments, the first interconnect layer 1406 may include trench structures 1428a and/or via structures 1428b, as shown. The trench structures 1428a of the first interconnect layer 1406 may be coupled with contacts (e.g., the S/D contacts 1424) of the device layer 1404.

A second interconnect layer 1408 (referred to as Metal 2 or “M2”) may be formed directly on the first interconnect layer 1406. In some embodiments, the second interconnect layer 1408 may include via structures 1428b to couple the trench structures 1428a of the second interconnect layer 1408 with the trench structures 1428a of the first interconnect layer 1406. Although the trench structures 1428a and the via structures 1428b are structurally delineated with a line within each interconnect layer (e.g., within the second interconnect layer 1408) for the sake of clarity, the trench structures 1428a and the via structures 1428b may be structurally and/or materially contiguous (e.g., simultaneously filled during a dual-damascene process) in some embodiments.

A third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 or the first interconnect layer 1406.

The IC device 1400 may include a solder resist material 1434 (e.g., polyimide or similar material) and one or more bond pads 1436 formed on the interconnect layers 1406-1410. The bond pads 1436 may be electrically coupled with the interconnect structures 1428 and configured to route the electrical signals of the transistor(s) 1440 to other external devices. For example, solder bonds may be formed on the one or more bond pads 1436 to mechanically and/or electrically couple a chip including the IC device 1400 with another component (e.g., a circuit board). The IC device 1400 may have other alternative configurations to route the electrical signals from the interconnect layers 1406-1410 than depicted in other embodiments. For example, the bond pads 1436 may be replaced by or may further include other analogous features (e.g., posts) that route the electrical signals to external components.

FIG. 15 is a cross-sectional side view of an IC device assembly 1500 that may include components having one or more transistor gate stacks with thick hysteretic elements in accordance with any of the embodiments disclosed herein. The IC device assembly 1500 includes a number of components disposed on a circuit board 1502 (which may be, e.g., a motherboard). The IC device assembly 1500 includes components disposed on a first face 1540 of the circuit board 1502 and an opposing second face 1542 of the circuit board 1502; generally, components may be disposed on one or both faces 1540 and 1542. In particular, any suitable ones of the components of the IC device assembly 1500 may include any of the transistor gate stacks 100 disclosed herein (e.g., in any of the transistors 120 disclosed herein).

In some embodiments, the circuit board 1502 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate.

The IC device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502 and may include solder balls (as shown in FIG. 15), male and female portions of a socket, an adhesive, an underfill material, and/or any other suitable electrical and/or mechanical coupling structure.

The package-on-interposer structure 1536 may include an IC package 1520 coupled to an interposer 1504 by coupling components 1518. The coupling components 1518 may take any suitable form for the application, such as the forms discussed above with reference to the coupling components 1516. Although a single IC package 1520 is shown in FIG. 15, multiple IC packages may be coupled to the interposer 1504; indeed, additional interposers may be coupled to the interposer 1504. The interposer 1504 may provide an intervening substrate used to bridge the circuit board 1502 and the IC package 1520. The IC package 1520 may be or include, for example, a die (the die 1302 of FIG. 13B), an IC device (e.g., the IC device 1400 of FIG. 14), or any other suitable component. Generally, the interposer 1504 may spread a connection to a wider pitch or reroute a connection to a different connection. For example, the interposer 1504 may couple the IC package 1520 (e.g., a die) to a ball grid array (BGA) of the coupling components 1516 for coupling to the circuit board 1502. In the embodiment illustrated in FIG. 15, the IC package 1520 and the circuit board 1502 are attached to opposing sides of the interposer 1504; in other embodiments, the IC package 1520 and the circuit board 1502 may be attached to a same side of the interposer 1504. In some embodiments, three or more components may be interconnected by way of the interposer 1504.

The interposer 1504 may be formed of an epoxy resin, a fiberglass-reinforced epoxy resin, a ceramic material, or a polymer material such as polyimide. In some implementations, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through-silicon vias (TSVs) 1506. The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art.

The IC device assembly 1500 may include an IC package 1524 coupled to the first face 1540 of the circuit board 1502 by coupling components 1522. The coupling components 1522 may take the form of any of the embodiments discussed above with reference to the coupling components 1516, and the IC package 1524 may take the form of any of the embodiments discussed above with reference to the IC package 1520.

The IC device assembly 1500 illustrated in FIG. 15 includes a package-on-package structure 1534 coupled to the second face 1542 of the circuit board 1502 by coupling components 1528. The package-on-package structure 1534 may include an IC package 1526 and an IC package 1532 coupled together by coupling components 1530 such that the IC package 1526 is disposed between the circuit board 1502 and the IC package 1532. The coupling components 1528 and 1530 may take the form of any of the embodiments of the coupling components 1516 discussed above, and the IC packages 1526 and 1532 may take the form of any of the embodiments of the IC package 1520 discussed above. The package-on-package structure 1534 may be configured in accordance with any of the package-on-package structures known in the art.

FIG. 16 is a block diagram of an example computing device 1600 that may include one or more components including one or more transistor gate stacks with thick hysteretic elements in accordance with any of the embodiments disclosed herein. For example, any suitable ones of the components of the computing device 1600 may include a die (e.g., the die 1302 (FIG. 13B)) having one or more transistors 120 including one or more transistor gate stacks 100. Any one or more of the components of the computing device 1600 may include, or be included in, an IC device 1400 (FIG. 14). Any one or more of the components of the computing device 1600 may include, or be included in, an IC device assembly 1500 (FIG. 15).

A number of components are illustrated in FIG. 16 as included in the computing device 1600, but any one or more of these components may be omitted or duplicated, as suitable for the application. In some embodiments, some or all of the components included in the computing device 1600 may be attached to one or more motherboards. In some embodiments, some or all of these components are fabricated onto a single system-on-a-chip (SoC) die.

Additionally, in various embodiments, the computing device 1600 may not include one or more of the components illustrated in FIG. 16, but the computing device 1600 may include interface circuitry for coupling to the one or more components. For example, the computing device 1600 may not include a display device 1612, but may include display device interface circuitry (e.g., a connector and driver circuitry) to which a display device 1612 may be coupled. In another set of examples, the computing device 1600 may not include an audio input device 1616 or an audio output device 1614 but may include audio input or output device interface circuitry (e.g., connectors and supporting circuitry) to which an audio input device 1616 or audio output device 1614 may be coupled.

The computing device 1600 may include a processing device 1602 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1600 may include a memory 1604, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1604 may include memory that shares a die with the processing device 1602. This memory may be used as cache memory and may include embedded dynamic random-access memory (eDRAM) or spin transfer torque magnetic random-access memory (STT-MRAM).

In some embodiments, the computing device 1600 may include a communication chip 1606 (e.g., one or more communication chips). For example, the communication chip 1606 may be configured for managing wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1606 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 1606 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1606 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1606 may operate in accordance with other wireless protocols in other embodiments. The computing device 1600 may include an antenna 1608 to facilitate wireless communications and/or to receive other wireless communications (such as AM or FM radio transmissions).

In some embodiments, the communication chip 1606 may manage wired communications, such as electrical, optical, or any other suitable communication protocols (e.g., the Ethernet). As noted above, the communication chip 1606 may include multiple communication chips. For instance, a first communication chip 1606 may be dedicated to shorter-range wireless communications such as Wi-Fi or Bluetooth, and a second communication chip 1606 may be dedicated to longer-range wireless communications such as global positioning system (GPS), EDGE, GPRS, CDMA, WiMAX, LTE, EV-DO, or others. In some embodiments, a first communication chip 1606 may be dedicated to wireless communications, and a second communication chip 1606 may be dedicated to wired communications.

The computing device 1600 may include a battery/power circuitry 1610. The battery/power circuitry 1610 may include one or more energy storage devices (e.g., batteries or capacitors) and/or circuitry for coupling components of the computing device 1600 to an energy source separate from the computing device 1600 (e.g., AC line power).

The computing device 1600 may include a display device 1612 (or corresponding interface circuitry, as discussed above). The display device 1612 may include any visual indicators, such as a heads-up display, a computer monitor, a projector, a touchscreen display, a liquid crystal display (LCD), a light-emitting diode display, or a flat panel display, for example.

The computing device 1600 may include an audio output device 1614 (or corresponding interface circuitry, as discussed above). The audio output device 1614 may include any device that generates an audible indicator, such as speakers, headsets, or earbuds, for example.

The computing device 1600 may include an audio input device 1616 (or corresponding interface circuitry, as discussed above). The audio input device 1616 may include any device that generates a signal representative of a sound, such as microphones, microphone arrays, or digital instruments (e.g., instruments having a musical instrument digital interface (MIDI) output).

The computing device 1600 may include an other output device 1618 (or corresponding interface circuitry, as discussed above). Examples of the other output device 1618 may include an audio codec, a video codec, a printer, a wired or wireless transmitter for providing information to other devices, or an additional storage device.

The computing device 1600 may include an other input device 1620 (or corresponding interface circuitry, as discussed above). Examples of the other input device 1620 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1600 may include a GPS device 1622 (or corresponding interface circuitry, as discussed above). The GPS device 1622 may be in communication with a satellite-based system and may receive a location of the computing device 1600, as known in the art.

The computing device 1600 may include a security interface device 1624. The security interface device 1624 may include any device that provides security features for the computing device 1600 or for any individual components therein (e.g., for the processing device 1602 or for the memory 1604). Examples of security features may include authorization, access to digital certificates, access to items in keychains, etc. Examples of the security interface device 1624 may include a software firewall, a hardware firewall, an antivirus, a content filtering device, or an intrusion detection device.

In some embodiments, the computing device 1600 may include a temperature detection device 1626 and a temperature regulation device 1628.

The temperature detection device 1626 may include any device capable of determining temperatures of the computing device 1600 or of any individual components therein (e.g., temperatures of the processing device 1602 or of the memory 1604). In various embodiments, the temperature detection device 1626 may be configured to determine temperatures of an object (e.g., the computing device 1600, components of the computing device 1600, devices coupled to the computing device, etc.), temperatures of an environment (e.g., a data center that includes, is controlled by, or otherwise associated with the computing device 1600), and so on. The temperature detection device 1626 may include one or more temperature sensors. Different temperature sensors of the temperature detection device 1626 may have different locations within and around the computing device 1600. A temperature sensor may generate data (e.g., digital data) representing detected temperatures and provide the data to another device, e.g., to the temperature regulation device 1628, the processing device 1602, the memory 1604, etc. In some embodiments, a temperature sensor of the temperature detection device 1626 may be turned on or off, e.g., by the processing device 1602 or an external system. The temperature sensor detects temperatures when it is on and does not detect temperatures when it is off. In other embodiments, a temperature sensor of the temperature detection device 1626 may detect temperatures continuously and automatically or detect temperatures at predefined times or at times triggered by an event associated with the computing device 1600 or any components therein.

The temperature regulation device 1628 may include any device configured to change (e.g., decrease) temperatures, e.g., based on one or more target temperatures and/or based on temperature measurements performed by the temperature detection device 1626. A target temperature may be a preferred temperature. A target temperature may depend on a setting in which the computing device 1600 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 1600 can be different. In some embodiments, cooling provided by the temperature regulation device 1628 may be a multi-stage process with temperatures ranging from room temperature to 4K or lower.

In some embodiments, the temperature regulation device 1628 may include one or more cooling devices. Different cooling device may have different locations within and around the computing device 1600. A cooling device of the temperature regulation device 1628 may be associated with one or more temperature sensors of the temperature detection device 1626 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 1600 is satisfied. In response to determining that one or more temperature-related condition associated with the temperature of the computing device 1600 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 1628 may operate with various cooling mechanisms, such as evaporation cooling, radiation cooling, conduction cooling, convection cooling, other cooling mechanisms, or any combination thereof. A cooling device of the temperature regulation device 1628 may include a cooling agent, such as a water, oil, liquid nitrogen, liquid helium, etc. In some embodiments, the temperature regulation device 1628 may be, for example, a dilution refrigerator, a helium-3 refrigerator, or a liquid helium refrigerator. In some embodiments, the temperature regulation device 1628 or any portions thereof (e.g., one or more of the individual cooling devices) may be connected to the computing device 1600 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 1600 (or components thereof) can be reduced, while the computing efficiency may be improved. For example, when the computing device 1600 (or components thereof) operates at lower temperatures, energy dissipation (e.g., heat dissipation) may be reduced. Further, energy consumed by semiconductor components (e.g., energy needed for switching transistors of any of the components of the computing device 1600) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 1600 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1600 may be any other electronic device that processes data.

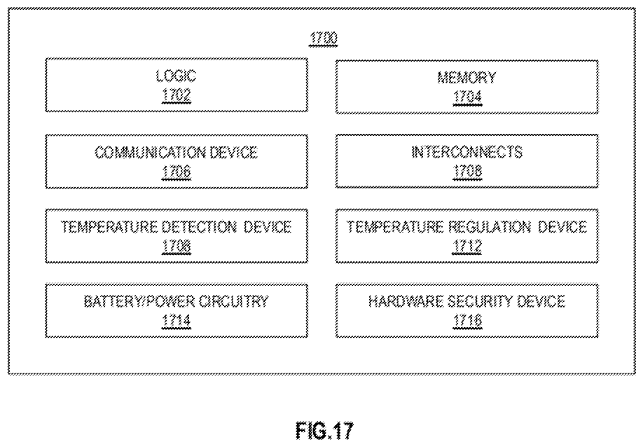

FIG. 17 is a block diagram of an example processing device 1700 that may include one or more transistor gate stacks with thick hysteretic elements in accordance with any of the embodiments disclosed herein. For example, any suitable ones of the components of the processing device 1700 may include a die (e.g., the die 1302 (FIG. 13B)) having one or more transistors 120 including one or more transistor gate stacks 100. Any one or more of the components of the processing device 1700 may include, or be included in, an IC device 1400 (FIG. 14). Any one or more of the components of the processing device 1700 may include, or be included in, an IC device assembly 1500 (FIG. 15). Any one or more of the components of the processing device 1700 may include, or be included in, a computing device 1600 (FIG. 16); for example, the processing device 1700 may be the processing device 1602 of the computing device 1600.

A number of components are illustrated in FIG. 17 as included in the processing device 1700, but any one or more of these components may be omitted or duplicated, as suitable for the application. In some embodiments, some or all of the components included in the processing device 1700 may be attached to one or more motherboards. In some embodiments, some or all of these components are fabricated on a single SoC die or coupled to a single support structure, e.g., to a single carrier substrate.

Additionally, in various embodiments, the processing device 1700 may not include one or more of the components illustrated in FIG. 17, but the processing device 1700 may include interface circuitry for coupling to the one or more components. For example, the processing device 1700 may not include a memory 1704, but may include display device interface circuitry (e.g., a connector and driver circuitry) to which a memory 1704 may be coupled.

The processing device 1700 may include logic circuitry 1702 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 1702 may include one or more circuits responsible for read/write operations with respect to the data stored in the memory 1704. To that end, the logic circuitry 1702 may include one or more I/O ICs configured to control access to data stored in the memory 1704.

In some embodiments, the logic circuitry 1702 may include one or more high-performance compute dies, configured to perform various operations with respect to data stored in the memory 1704 (e.g., arithmetic and logic operations, pipelining of data from one or more memory dies of the memory 1704, and possibly also data from external devices/chips). In some embodiments, the logic circuitry 1702 may be configured to only control I/O access to data but not perform any operations on the data. In some embodiments, the logic circuitry 1702 may implement ICs configured to implement I/O control of data stored in the memory 1704, assemble data from the memory 1704 for transport (e.g., transport over a central bus) to devices/chips that are either internal or external to the processing device 1700, etc. In some embodiments, the logic circuitry 1702 may not be configured to perform any operations on the data besides I/O and assembling for transport to the memory 1704.

The processing device 1700 may include a memory 1704, which may include one or more ICs configure to implement memory circuitry (e.g., ICs implementing one or more of memory devices, memory arrays, control logic configured to control the memory devices and arrays, etc.). In some embodiments, the memory 1704 may be implemented substantially as described above with reference to the memory 1604 (FIG. 16). In some embodiments, the memory 1704 may be a designated device configured to provide storage functionality for the components of the processing device 1700 (i.e., local), while the memory 1604 may be configured to provide system-level storage functionality for the entire computing device 1600 (i.e., global). In some embodiments, the memory 1704 may include memory that shares a die with the logic circuitry 1702.

In some embodiments, the memory 1704 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 1704 may be a memory that is not divided into hierarchical layer or levels in terms of access of its data.

In some embodiments, the memory 1704 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 1704 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 1704 may be arranged.

The processing device 1700 may include a communication device 1706, which may be implemented substantially as described above with reference to the communication chip 1606 (FIG. 16). In some embodiments, the communication device 1706 may be a designated device configured to provide communication functionality for the components of the processing device 1700 (i.e., local), while the communication chip 1606 may be configured to provide system-level communication functionality for the entire computing device 1600 (i.e., global).

The processing device 1700 may include interconnects 1708, which may include any element or device that includes an electrically conductive material for providing electrical connectivity to one or more components of, or associated with, a processing device 1700 or/and between various such components. Examples of the interconnects 1708 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 1700 may include a temperature detection device 1710 which may be implemented substantially as described above with reference to the temperature detection device 1626 (FIG. 16) but configured to determine temperatures on a more local scale, i.e., of the processing device 1700 of components thereof. In some embodiments, the temperature detection device 1710 may be a designated device configured to provide temperature detection functionality for the components of the processing device 1700 (i.e., local), while the temperature detection device 1626 may be configured to provide system-level temperature detection functionality for the entire computing device 1600 (i.e., global).

The processing device 1700 may include a temperature regulation device 1712 which may be implemented substantially as described above with reference to the temperature regulation device 1628 (FIG. 16) but configured to regulate temperatures on a more local scale, i.e., of the processing device 1700 of components thereof. In some embodiments, the temperature regulation device 1712 may be a designated device configured to provide temperature regulation functionality for the components of the processing device 1700 (i.e., local), while the temperature regulation device 1628 may be configured to provide system-level temperature regulation functionality for the entire computing device 1600 (i.e., global).

The processing device 1700 may include a battery/power circuitry 1714 which may be implemented substantially as described above with reference to the battery/power circuitry 1610 (FIG. 16). In some embodiments, the battery/power circuitry 1714 may be a designated device configured to provide battery/power functionality for the components of the processing device 1700 (i.e., local), while the battery/power circuitry 1610 may be configured to provide system-level battery/power functionality for the entire computing device 1600 (i.e., global).

The processing device 1700 may include a hardware security device 1716 which may be implemented substantially as described above with reference to the security interface device 1624 (FIG. 16). In some embodiments, the hardware security device 1716 may be a physical computing device configured to safeguard and manage digital keys, perform encryption and decryption functions for digital signatures, authentication, and other cryptographic functions. In some embodiments, the hardware security device 1716 may include one or more secure cryptoprocessors chips.

The following paragraphs provide various examples of the embodiments disclosed herein.

Example 1 provides an IC device that includes a transistor gate-channel arrangement, including a channel material and a transistor gate stack, where the transistor gate stack includes a gate electrode material, a hysteretic element between the gate electrode material and the channel material, and an interface layer between the hysteretic element and the channel material, and where a thickness of the hysteretic element is greater than about 15 nanometers.

Example 2 provides the IC device according to example 1, where the thickness of the hysteretic element is greater than about 25 nanometers or greater than about 50 nanometers, e.g., between about 50 nanometers and 110 nanometers.

Example 3 provides the IC device according to any one of examples 1-2, where the gate electrode material is in contact with the hysteretic element.

Example 4 provides the IC device according to any one of examples 1-3, where the hysteretic element is in contact with the interface layer.

Example 5 provides the IC device according to any one of examples 1-4, where a dielectric constant of the interface layer is greater than 20.

Example 6 provides the IC device according to any one of examples 1-5, where a thickness of the interface layer is smaller than about 3 nanometers, e.g., smaller than about 2 nanometers or smaller than about 1 nanometer.

Example 7 provides the IC device according to any one of examples 1-6, where the interface layer includes silicon and oxygen, e.g., silica.

Example 8 provides the IC device according to any one of examples 1-7, where the interface layer includes oxygen and one or more rare-earth elements (e.g., the interface layer may include one or more rare-earth metal oxides such as yttrium oxide, lanthanum oxide, etc.).

Example 9 provides the IC device according to any one of examples 1-7, where the interface layer includes a metal (e.g., hafnium, zirconium, lanthanum, aluminum, tantalum, etc.) and oxygen.

Example 10 provides the IC device according to any one of examples 1-6, where the interface layer includes a two-dimensional (2D) material.

Example 11 provides the IC device according to example 10, where the 2D material includes a single layer of the 2D material.

Example 12 provides the IC device according to example 10, where the 2D material includes five or fewer layers of the 2D material.

Example 13 provides the IC device according to any one of examples 10-12, where the 2D material includes graphene.

Example 14 provides the IC device according to any one of examples 10-12, where the 2D material includes boron disulfide.

Example 15 provides the IC device according to any one of examples 10-12, where the 2D material includes a metal chalcogenide.

Example 16 provides the IC device according to any one of examples 1-15, where the interface layer is in contact with the channel material.

Example 17 provides the IC device according to any one of examples 1-15, further including an additional interface layer between the interface layer and the channel material, where the interface layer is in contact with the additional interface layer and the additional interface layer is in contact with the channel material.

Example 18 provides the IC device according to example 17, where the additional interface layer includes a hysteretic material.

Example 19 provides the IC device according to any one of examples 17-18, where the additional interface layer includes an insulator material, and where at least 5% of the insulator material is in one or more of a tetragonal phase and an orthorhombic phase.

Example 20 provides the IC device according to any one of examples 17-19, where the additional interface layer includes hafnium, oxygen, and one or more dopants, where the one or more dopants include one or more of zirconium, yttrium, silicon, germanium, and aluminum.

Example 21 provides the IC device according to any one of examples 17-20, where the additional interface layer includes oxygen and one or more rare-earth elements (e.g., the interface layer may include one or more rare-earth oxides such as yttrium oxide, lanthanum oxide, etc.).

Example 22 provides the IC device according to any one of examples 17-21, where the additional interface layer includes a metal (e.g., hafnium, zirconium, lanthanum, aluminum, tantalum, etc.) and oxygen.

Example 23 provides the IC device according to any one of examples 17-22, where the additional interface layer includes nitrogen in concentration of at least about 10¹⁶ nitrogen atoms per cubic centimeter, e.g., in concentration between about 10¹⁶ nitrogen atoms per cubic centimeter and about 10²⁰ nitrogen atoms per cubic centimeter.

Example 24 provides the IC device according to any one of examples 17-23, where a thickness of the additional interface layer is smaller than about 3 nanometers.

Example 25 provides the IC device according to example 24, where the thickness of the additional interface layer is between about 0.5 and 3 nanometers.

Example 26 provides the IC device according to any one of examples 1-25, where the hysteretic element includes a hysteretic material.

Example 27 provides the IC device according to any one of examples 1-26, where the hysteretic element includes an insulator material, and where at least 5% of the insulator material is in one or more of a tetragonal phase and an orthorhombic phase.

Example 28 provides the IC device according to any one of examples 1-27, where the hysteretic element includes hafnium, oxygen, and one or more dopants, where the one or more dopants include one or more of zirconium, yttrium, silicon, germanium, and aluminum.

Example 29 provides the IC device according to any one of examples 1-28, where the hysteretic element includes oxygen and one or more rare-earth elements (e.g., the interface layer may include one or more rare-earth oxides such as yttrium oxide, lanthanum oxide, etc.).

Example 30 provides the IC device according to any one of examples 1-29, where the hysteretic element includes a metal (e.g., hafnium, zirconium, lanthanum, aluminum, tantalum, etc.) and oxygen.

Example 31 provides the IC device according to any one of examples 1-30, where the hysteretic element includes nitrogen in concentration of at least about 10¹⁶ nitrogen atoms per cubic centimeter, e.g., in concentration between about 10¹⁶ nitrogen atoms per cubic centimeter and about 10²⁰ nitrogen atoms per cubic centimeter.

Example 32 provides the IC device according to any one of examples 1-25, where the hysteretic element includes a hysteretic arrangement including at least a first layer (e.g., a charge-trapping layer) and a second layer (e.g., a tunnelling layer), the first layer includes a sub-stoichiometric material (i.e., a material that includes less than a stochiometric amount of a reagent), and the second layer includes an insulator material.

Example 33 provides the IC device according to example 32, where the sub-stoichiometric material includes vacancies in concentration of at least about 10¹⁸ vacancies per cubic centimeter, e.g., in concentration between about 10¹⁸ vacancies per cubic centimeter and about 10²²-10²³ vacancies per cubic centimeter.

Example 34 provides the IC device according to example 33, where the sub-stoichiometric material includes oxygen and where the vacancies are oxygen vacancies.

Example 35 provides the IC device according to example 33, where the sub-stoichiometric material includes nitrogen and where the vacancies are nitrogen vacancies.

Example 36 provides the IC device according to example 35, where the sub-stoichiometric material further includes silicon, e.g., the sub-stoichiometric material is silicon nitride.

Example 37 provides the IC device according to any one of examples 33-36, where the sub-stoichiometric material further includes a metal or a semiconductor.

Example 38 provides the IC device according to any one of examples 32-37, where the first layer is between (e.g., in contact with each of) the gate electrode material and the second layer, and the second layer is between (e.g., in contact with each of) the first layer and the interface layer.

Example 39 provides the IC device according to any one of examples 32-37, where the first layer is between (e.g., in contact with each of) the interface layer and the second layer, and the second layer is between (e.g., in contact with each of) the first layer and the gate electrode material.

Example 40 provides the IC device according to any one of examples 32-37, where the hysteretic arrangement further includes a third layer, and the third layer includes an insulator material, and the first layer is between (e.g., in contact with each of) the second layer and the third layer.

Example 41 provides the IC device according to any one of examples 1-40, where the channel material includes IGZO, tin oxide, antimony oxide, indium oxide, indium tin oxide, titanium oxide, zinc oxide, indium zinc oxide, gallium oxide, titanium oxynitride, ruthenium oxide, or tungsten oxide.

Example 42 provides the IC device according to any one of examples 1-41, where the channel material includes a semiconductor having an average grain size smaller than about 1 millimeter.

Example 43 provides the IC device according to any one of examples 1-41, where the channel material includes a semiconductor having an average grain size larger than about 1 millimeter.

Example 44 provides the IC device according to any one of examples 1-43, where the IC device includes a transistor, and the transistor gate-channel arrangement is a part of the transistor.

Example 45 provides the IC device according to example 44, where the transistor further includes a source region and a drain region.

Example 46 provides the IC device according to any one of examples 44-45, where the transistor has a gate length between 3 and 30 nanometers.

Example 47 provides the IC device according to any one of examples 44-46, where the channel material is coplanar with the source region and the drain region.

Example 48 provides the IC device according to any one of examples 44-46, where the channel material is shaped as a fin, the interface layer wraps around a top portion of the fin, and the hysteretic element wraps around the interface layer.

Example 49 provides the IC device according to any one of examples 44-46, where the channel material is shaped as a nanoribbon, the interface layer wraps around the nanoribbon, and the hysteretic element wraps around the interface layer.

Example 50 provides the IC device according to example 49, where the interface layer wraps entirely around the nanoribbon and the hysteretic element wraps entirely around the interface layer.

Example 51 provides an IC device that includes a transistor with a channel material and a gate, where the gate includes a gate electrode material. The IC device further includes a hysteretic element between the gate electrode material and the channel material, and an interface layer between the hysteretic element and the channel material, where a thickness of the hysteretic element is greater than about 15 nanometers.

Example 52 provides the IC device according to example 51, further including features according to any one of examples 1-50.

Example 53 provides an IC package that includes an IC die, the IC die including an IC device according to any one of the preceding examples (e.g., any one of examples 1-52). The IC package also includes a further component, coupled to the IC die.

Example 54 provides the IC package according to example 53, where the further component is one of a package substrate, an interposer, or a further IC die.

Example 55 provides the IC package according to any one of examples 53-54, where the further component is coupled to the IC die via one or more first level interconnects, and the one or more first level interconnects include one or more solder bumps, solder posts, or bond wires.

Example 56 provides an electronic device, including a carrier substrate; and one or more of the IC devices according to any one of the preceding examples and/or the IC package according to any one of the preceding examples, coupled to the carrier substrate.

Example 57 provides the electronic device according to example 56, where the carrier substrate is a motherboard.

Example 58 provides the electronic device according to example 56, where the carrier substrate is a PCB.

Example 59 provides the electronic device according to any one of examples 56-58, where the electronic device is a wearable electronic device (e.g., a smart watch) or handheld electronic device (e.g., a mobile phone).

Example 60 provides the electronic device according to any one of examples 56-59, where the electronic device further includes one or more communication chips and an antenna.

Example 61 provides the electronic device according to any one of examples 56-60, where the electronic device is memory device.

Example 62 provides the electronic device according to any one of examples 56-60, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 63 provides the electronic device according to any one of examples 56-60, where the electronic device is a computing device.

Example 64 provides the electronic device according to any one of examples 56-63, where the electronic device is included in a base station of a wireless communication system.

Example 65 provides the electronic device according to any one of examples 56-63, where the electronic device is included in a user equipment device (i.e., a mobile device) of a wireless communication system.

Example 66 provides a method of manufacturing an IC device that includes a transistor, the method including providing a transistor that includes a channel material and a gate, where the gate includes a gate electrode material; providing a hysteretic element between the gate electrode material and the channel material; and providing an interface layer between the hysteretic element and the channel material, where a thickness of the hysteretic element is greater than about 15 nanometers.

Example 67 provides the method according to example 66, where providing the interface layer includes performing ALD, physical vapor deposition, or CVD of the interface layer.

Example 68 provides the method according to any one of examples 66-67, further including providing a source region and a drain region on either side of the gate.

Example 69 provides the method according to any one of examples 66-68, where the interface layer at least partially wraps around the channel material.

Example 70 provides the method according to example 69, where the interface layer encircles the channel material.

Example 71 provides the method according to any one of examples 66-70, further including processes for forming the IC device according to any one of the preceding examples (e.g., any one of examples 1-52).

Example 72 provides the method according to any one of examples 66-71, further including processes for forming an IC package according to any one of the preceding examples (e.g., any one of examples 53-55).

Example 73 provides the method according to any one of examples 66-72, further including processes for forming an electronic device according to any one of the preceding examples (e.g., any one of examples 56-65).

1. An integrated circuit (IC) device, comprising:
a transistor gate-channel arrangement, comprising a channel material and a transistor gate stack,
wherein:
the transistor gate stack includes a gate electrode material, a hysteretic element between the gate electrode material and the channel material, and an interface layer between the hysteretic element and the channel material, and
a thickness of the hysteretic element is at least 15 nanometers.

2. The IC device according to claim 1, wherein the thickness of the hysteretic element is between 50 nanometers and 110 nanometers.

3. The IC device according to claim 1, wherein a dielectric constant of the interface layer is at least 20 and a thickness of the interface layer is below 3 nanometers.

4. The IC device according to claim 1, wherein the interface layer includes at least one of:
a material comprising silicon and oxygen,
a material comprising oxygen and one or more rare-earth elements,
a material comprising a metal and oxygen, and
a two-dimensional material.

5. The IC device according to claim 1, wherein the interface layer includes at least one of:
graphene,
boron disulfide, and
a metal chalcogenide.

6. The IC device according to claim 1, further comprising an additional interface layer between the interface layer and the channel material.

7. The IC device according to claim 6, wherein the additional interface layer includes a ferroelectric material, and wherein the ferroelectric material includes hafnium, oxygen, and one or more dopants, wherein the one or more dopants include one or more of zirconium, yttrium, silicon, germanium, and aluminum.

8. The IC device according to claim 7, wherein a thickness of the additional interface layer is below 3 nanometers.

9. The IC device according to claim 1, wherein the hysteretic element includes an insulator material, and wherein at least 5% of the insulator material is in one or more of a tetragonal phase and an orthorhombic phase.

10. The IC device according to claim 9, wherein the hysteretic element includes nitrogen in concentration of at least about 10¹⁶ atoms per cubic centimeter.

11. The IC device according to claim 1, wherein:
the hysteretic element includes a hysteretic arrangement comprising at least a first layer and a second layer,
the first layer includes a sub-stoichiometric material with vacancies in concentration of at least about 10¹⁸ vacancies per cubic centimeter, and
the second layer includes an insulator material.

12. The IC device according to claim 11, wherein the sub-stoichiometric material includes oxygen and wherein the vacancies are oxygen vacancies.

13. The IC device according to claim 11, wherein the sub-stoichiometric material includes silicon and nitrogen, and wherein the vacancies are nitrogen vacancies.

14. The IC device according to claim 11, wherein:
the hysteretic arrangement further includes a third layer, and
the third layer includes an insulator material, and the first layer is between the second layer and the third layer.

15. The IC device according to claim 1, wherein the channel material includes a semiconductor having an average grain size smaller than about 1 millimeter.

16. The IC device according to claim 1, wherein the channel material includes a semiconductor having an average grain size larger than about 1 millimeter.

17. An integrated circuit (IC) package, comprising:
an IC die, comprising:
a transistor, comprising a channel material and a gate, the gate comprising a gate electrode material,
a hysteretic element between the gate electrode material and the channel material of the transistor, the hysteretic element having a thickness of at least 15 nanometers, and an interface layer between the hysteretic element and the channel material; and
a further component, coupled to the IC die.

18. The IC package according to claim 17, wherein the further component is one of a package substrate, an interposer, or a further IC die.

19. A method of manufacturing an IC device, the method comprising:
providing a transistor that includes a channel material and a gate, wherein the gate includes a gate electrode material;
providing a hysteretic element between the gate electrode material and the channel material; and
providing an interface layer between the hysteretic element and the channel material, wherein a thickness of the hysteretic element is between about 50 nanometers and 100 nanometers.

20. The method according to claim 19, wherein providing the interface layer comprises performing atomic layer deposition, physical vapor deposition, or chemical vapor deposition of the interface layer.
